(19) United States
(12) Patent Application Publication
(10) Pub. No.: US 2022/0384526 A1
(43) Pub. Date: Dec. 1, 2022

(54) Display Device, Display Module, and Electronic Device

(71) Applicant: Semiconductor Energy Laboratory Co., Ltd., Kanagawa-ken (JP)

(72) Inventors: Shunpei Yamazaki, Setagaya, Tokyo (JP); Kenichi OKAZAKI, Tochigi, Tochigi (JP)

(73) Assignee: Semiconductor Energy Laboratory Co., Ltd., Kanagawa-ken (JP)

(21) Appl. No.: 17/772,273

(22) PCT Filed: Oct. 26, 2020
(86) PCT No.: PCT/IB2020/060014

§ 371 Date: Apr. 27, 2022

(30) Foreign Application Priority Data
Nov. 8, 2019 (JP) 2019-203123

(51) Int. Cl. H01L 27/28; H01L 27/32; H01L 27/30

(52) U.S. Cl. CPC H01L 27/288; H01L 27/3258; H01L 27/307; H01L 27/3234; G06V 40/1318

(57) ABSTRACT

A display device includes a first pixel circuit including a light-receiving element and a first transistor, and a second pixel circuit including a light-emitting element and a second transistor. The light-receiving element includes an active layer between a first pixel electrode and a common electrode, and the light-emitting element includes a light-emitting layer between a second pixel electrode and the common electrode. The first pixel electrode and the second pixel electrode are positioned on the same plane. The active layer and the light-emitting layer contain different organic compounds. A source or a drain of the first transistor is electrically connected to the first pixel electrode, and a source or a drain of the second transistor is electrically connected to the second pixel electrode. The first transistor includes a first semiconductor layer containing a metal oxide, and the second transistor includes a second semiconductor layer containing polycrystalline silicon.

### TECHNICAL FIELD

One embodiment of the present invention relates to a display device. One embodiment of the present invention relates to a display device with an imaging function.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device refers to a device that can function by utilizing semiconductor characteristics in general.

### BACKGROUND ART

In recent years, display devices are used in various devices such as information terminal devices (e.g., smartphones, tablet terminals, and notebook personal computers (PCs)), television devices, and monitor devices. Furthermore, in recent years, display devices have been required to have a variety of functions such as a touch panel function and a function of capturing an image of a fingerprint for authentication in addition to a function of displaying images.

Light-emitting apparatuses including light-emitting elements have been developed as display devices. Light-emitting elements utilizing electroluminescence (hereinafter referred to as EL elements) have features such as ease of reduction in thickness and weight, high-speed response to input signals, and capability of DC low voltage driving, and have been used in display devices. Patent Document 1, for example, discloses a flexible light-emitting apparatus in which an organic EL element is used.

### REFERENCE

### [Patent Document]

Patent Document 1: Japanese Published Patent Application No. 2014-197522

### DISCLOSURE OF INVENTION

An object of one embodiment of the present invention is to provide a display device having an imaging function. An object of one embodiment of the present invention is to provide a highly functional display device. An object of one embodiment of the present invention is to provide a display device capable of displaying an image with high display quality. An object of one embodiment of the present invention is to provide a display device capable of favorably capturing an image.

Note that the description of these objects does not disturb the existence of other objects. One embodiment of the present invention does not need to achieve all the objects. Objects other than these can be derived from the description of the specification, the drawings, the claims, and the like.

One embodiment of the present invention is a display device including a first pixel circuit and a second pixel circuit. The first pixel circuit includes a light-receiving element and a first transistor. The second pixel circuit includes a light-emitting element and a second transistor. The light-receiving element includes a first pixel electrode, an active layer, and a common electrode. The light-emitting element includes a second pixel electrode, a light-emitting layer, and the common electrode. The first pixel electrode and the second pixel electrode are positioned on the same plane. The active layer is positioned over the first pixel electrode and contains a first organic compound. The light-emitting layer is positioned over the second pixel electrode and contains a second organic compound different from the first organic compound. The common electrode includes a portion overlapping with the first pixel electrode with the active layer therebetween, and a portion overlapping with the second pixel electrode with the light-emitting layer therebetween. One of a source and a drain of the first transistor is electrically connected to the first pixel electrode, and one of a source and a drain of the second transistor is electrically connected to the second pixel electrode. The first transistor and the second transistor contain polycrystalline silicon in their respective semiconductor layers.

In the above, each of the first transistor and the second transistor preferably includes a first gate and a second gate that overlap with each other with the semiconductor layer therebetween. In this case, the first gate and the second gate are preferably electrically connected to each other.

Another embodiment of the present invention is a display device including a first pixel circuit and a second pixel circuit. The first pixel circuit includes a light-receiving element and a first transistor. The second pixel circuit includes a light-emitting element and a second transistor. The light-receiving element includes a first pixel electrode, an active layer, and a common electrode. The light-emitting element includes a second pixel electrode, a light-emitting layer, and the common electrode. The first pixel electrode and the second pixel electrode are positioned on the same plane. The active layer is positioned over the first pixel electrode and contains a first organic compound. The light-emitting layer is positioned over the second pixel electrode and contains a second organic compound different from the first organic compound. The common electrode includes a portion overlapping with the first pixel electrode with the active layer therebetween, and a portion overlapping with the second pixel electrode with the light-emitting layer therebetween. One of a source and a drain of the first transistor is electrically connected to the first pixel electrode, and one of a source and a drain of the second transistor is electrically connected to the second pixel electrode. The first transistor includes a first semiconductor layer containing a metal oxide, and the second transistor includes a second semiconductor layer containing polycrystalline silicon.

In the above, the first transistor preferably includes a third gate positioned over the first semiconductor layer and a fourth gate overlapping with the third gate with the first semiconductor layer therebetween. The second transistor preferably includes a fifth gate positioned over the second semiconductor layer and a sixth gate overlapping with the fifth gate with the second semiconductor layer therebetween. In this case, it is preferable that the fourth gate and the fifth gate be positioned on the same plane and contain the same metal element.

In the above, it is preferable that the source and the drain of the first transistor and the source and the drain of the second transistor be positioned on the same plane and contain the same metal element.

Furthermore, in the above, a common layer is preferably included. In this case, the common layer preferably includes a portion overlapping with the active layer between the first pixel electrode and the common electrode and a portion overlapping with the light-emitting layer between the second pixel electrode and the common electrode.

Alternatively, in the above, a first common layer and a second common layer are preferably included. In this case, the first common layer preferably includes a portion positioned between the first pixel electrode and the active layer and a portion positioned between the second pixel electrode and the light-emitting layer. The second common layer preferably includes a portion positioned between the active layer and the common electrode and a portion positioned between the light-emitting layer and the common electrode.

In the above, the first pixel circuit preferably includes a third transistor. In this case, the third transistor preferably contains polycrystalline silicon in its semiconductor layer.

In the above, the second pixel circuit preferably includes a fourth transistor. In this case, the fourth transistor preferably contains a metal oxide in its semiconductor layer.

In the above, a first substrate and a second substrate are preferably included. In this case, the first transistor and the second transistor are preferably positioned between the first substrate and the second substrate. Furthermore, it is preferable that the first pixel electrode be positioned between the first transistor and the second substrate and the second pixel electrode be positioned between the second transistor and the second substrate. In addition, the first substrate and the second substrate are preferably flexible.

Another embodiment of the present invention is a display module including any one of the display devices, and a connector or an integrated circuit.

Another embodiment of the present invention is an electronic device including the above-described display module and at least one of an antenna, a battery, a housing, a camera, a speaker, a microphone, and an operation button.

With one embodiment of the present invention, a display device having an imaging function can be provided. Alternatively, a highly functional display device can be provided. Alternatively, a display device capable of displaying an image with high display quality can be provided. Alternatively, a display device capable of favorably capturing an image can be provided.

Note that the description of the effects does not disturb the existence of other effects. One embodiment of the present invention does not need to have all the effects. Effects other than these can be derived from the description of the specification, the drawings, the claims, and the like.

### BRIEF DESCRIPTION OF DRAWINGS

In the accompanying drawings:

FIG. 1A illustrates a structure example of a display device, and FIGS. 1B and 1C are circuit diagrams of pixel circuits;

FIGS. 2A and 2B are timing charts each showing a method for driving a display device;

FIGS. 3A and 3B are each a circuit diagram of a pixel circuit;

FIGS. 4A to 4C are each a circuit diagram of a pixel circuit;

FIGS. 5A and 5B are each a schematic cross-sectional view of a display device;

FIGS. 6A and 6B are each a schematic cross-sectional view of a display device;

FIGS. 7A, 7B, 7D, and 7F to 7H illustrate structure examples of a display device, and FIGS. 7C and 7E illustrate examples of images;

FIGS. 8A to 8D illustrate structure examples of a display device;

FIGS. 9A to 9C each illustrate a structure example of a display device;

FIGS. 10A and 10B each illustrate a structure example of a display device;

FIGS. 11A to 11C each illustrate a structure example of a display device;

FIG. 12 illustrates a structure example of a display device;

FIG. 13 illustrates a structure example of a display device;

FIG. 14 illustrates a structure example of a display device;

FIG. 15A illustrates a structure example of a display system, and FIGS. 15B and 15C illustrate usage examples of the display system;

FIGS. 16A and 16B illustrate a structure example of an electronic device;

FIGS. 17A to 17D illustrate structure examples of electronic devices; and

FIGS. 18A to 18F illustrate structure examples of electronic devices.

### BEST MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number of components.

A transistor is a kind of semiconductor element and enables amplification of current or voltage, switching operation for controlling conduction or non-conduction, and the like. A transistor in this specification includes, in its category, an insulated-gate field effect transistor (IGFET) and a thin film transistor (TFT).

Furthermore, functions of a “source” and a “drain” might be switched when a transistor of opposite polarity is employed or a direction of current flow is changed in circuit operation, for example. Therefore, the terms “source” and “drain” can be interchanged with each other in this specification.

In this specification and the like, the term “electrically connected” includes the case where components are connected through an “object having any electric function”. There is no particular limitation on an “object having any electric function” as long as electric signals can be transmitted and received between components that are connected through the object. Examples of an “object having any electric function” are a switching element such as a transistor, a resistor, a coil, a capacitor, and an element with a variety of functions as well as an electrode and a wiring.

In this specification and the like, a display panel that is one embodiment of a display device has a function of displaying (outputting) an image or the like on (to) a display surface. Thus, the display panel is one embodiment of an output device.

In this specification and the like, a structure in which a connector such as a flexible printed circuit (FPC) or a tape carrier package (TCP) is attached to a substrate of a display panel, or a structure in which an integrated circuit (IC) is mounted on a substrate by a chip on glass (COG) method or the like is referred to as a display panel module or a display module, or simply referred to as a display panel or the like in some cases.

Note that in this specification and the like, a touch panel that is one embodiment of a display device has a function of displaying an image or the like on a display surface and a function of a touch sensor capable of sensing the contact, press, approach, or the like of a sensing target such as a finger or a stylus with or to the display surface. Therefore, the touch panel is one embodiment of an input/output device.

A touch panel can also be referred to as, for example, a display panel (or a display device) with a touch sensor or a display panel (or a display device) having a touch sensor function. A touch panel can include a display panel and a touch sensor panel. Alternatively, a touch panel can have a function of a touch sensor inside a display panel or on a surface thereof.

In this specification and the like, a structure in which a connector, an IC, or the like is attached to a substrate of a touch panel is referred to as a touch panel module or a display module, or simply referred to as a touch panel or the like in some cases.

### Embodiment 1

In this embodiment, a display device of one embodiment of the present invention is described.

A display device of one embodiment of the present invention includes light-receiving elements (also referred to as light-receiving devices) and light-emitting elements (also referred to as light-emitting devices) in a display portion. The light-emitting elements are arranged in a matrix in the display portion, and an image can be displayed on the display portion using the light-emitting elements. In addition, the light-receiving elements are arranged in a matrix in the display portion, and thus the display portion functions as a light-receiving portion. An image can be captured by the plurality of light-receiving elements provided in the display portion, so that the display device can function as an image sensor, a touch panel, or the like. That is, the display portion can capture an image and sense an approach or a contact of an object (e.g., a finger or a pen). Furthermore, since the light-emitting elements provided in the display portion can be used as light sources at the time of receiving light, a light source does not need to be provided separately from the display device; thus, a highly functional display device can be provided without increasing the number of components of an electronic device.

In one embodiment of the present invention, when an object reflects light emitted from the light-emitting element included in the display portion, the light-receiving element can sense the reflected light; thus, image capturing and touch (including non-contact touch) sensing can be performed even in a dark environment.

Furthermore, when a finger, a palm, or the like touches the display portion of the display device of one embodiment of the present invention, an image of the fingerprint, the palm print, or the like can be captured. Thus, an electronic device including the display device of one embodiment of the present invention can perform personal authentication by using the captured fingerprint. Accordingly, an imaging device for the fingerprint authentication or palm-print authentication does not need to be additionally provided, and the number of components of the electronic device can be reduced. Furthermore, since the light-receiving elements are arranged in a matrix in the display portion, an image of a fingerprint, a palm print, or the like can be captured in any portion in the display portion, which can provide a convenient electronic device.

As the light-emitting element, an EL element such as an organic light-emitting diode (OLED) or a quantum-dot light-emitting diode (QLED) is preferably used. As a light-emitting substance included in the EL element, a substance emitting fluorescence (a fluorescent material), a substance emitting phosphorescence (a phosphorescent material), a substance exhibiting thermally activated delayed fluorescence (a thermally activated delayed fluorescent (TADF) material), an inorganic compound (e.g., a quantum dot material), or the like can be used. Alternatively, a light-emitting diode (LED) such as a micro-LED can be used as the light-emitting element.

As the light-receiving element, a PN photodiode or a PIN photodiode can be used, for example. The light-receiving element functions as a photoelectric conversion element that senses light incident on the light-receiving element and generates charge. The amount of generated charge in the photoelectric conversion element is determined depending on the amount of incident light. It is particularly preferable to use an organic photodiode including a layer containing an organic compound as the light-receiving element. An organic photodiode, which is easily made thin, lightweight, and large in area and has a high degree of freedom for shape and design, can be used in a variety of display devices.

The light-emitting element can have a stacked-layer structure including a light-emitting layer between a pair of electrodes, for example. The light-receiving element can have a stacked-layer structure including an active layer between a pair of electrodes. A semiconductor material can be used for the active layer of the light-receiving element. For example, an inorganic semiconductor material such as silicon can be used.

An organic compound is preferably used for the active layer of the light-receiving element. In that case, one electrode (a pixel electrode) of the light-emitting element and one electrode (a pixel electrode) of the light-receiving element are preferably provided on the same plane. It is further preferable that the other electrode of the light-emitting element and the other electrode of the light-receiving element be an electrode (a common electrode) formed using one continuous conductive layer. It is still further preferable that the light-emitting element and the light-receiving element include a common layer. Thus, the manufacturing process of the light-emitting element and the light-receiving element can be simplified, so that the manufacturing cost can be reduced and the manufacturing yield can be increased.

Here, the display portion can have a structure in which first pixel circuits each including the light-receiving element and one or more transistors are arranged in a matrix and second pixel circuits each including the light-emitting element and one or more transistors are arranged in a matrix.

In the display device of one embodiment of the present invention, it is preferable to use transistors containing silicon in their semiconductor layers where channels are formed as all of the transistors included in the first pixel circuit including the light-receiving element and the second pixel circuit including the light-emitting element. Examples of silicon include single crystal silicon, polycrystalline silicon, and amorphous silicon. In particular, transistors containing low-temperature polysilicon (LTPS) in their semiconductor layers (such transistors are referred to as LTPS transistors below) are preferably used. The LTPS transistor has high field-effect mobility and excellent frequency characteristics.

With the use of the transistors using silicon such as the LTPS transistors, a circuit required to drive at a high frequency (e.g., a source driver circuit) can be formed on the same substrate as the display portion. This allows simplification of an external circuit mounted on the display device and a reduction in costs of parts, mounting costs, and the like.

It is preferable to use a transistor containing a metal oxide (also referred to as an oxide semiconductor below) in a semiconductor layer where a channel is formed (such a transistor is also referred to as an OS transistor below) as at least one of the transistors included in the first pixel circuit and the second pixel circuit. The OS transistor has much higher field-effect mobility than a transistor containing amorphous silicon. In addition, the OS transistor has an extremely low leakage current between a source and a drain in an off state (the leakage current is also referred to as an off-state current below), and charge accumulated in a capacitor that is connected in series to the transistor can be held for a long period. Furthermore, the power consumption of the display device can be reduced with the OS transistor.

When an LTPS transistor is used as one or more of the transistors included in the first pixel circuits and the second pixel circuits and an OS transistor is used as the rest, the display device can have low power consumption and high drive capability. As a favorable example, it is preferable that the OS transistor be used as a transistor functioning as a switch for controlling conduction or non-conduction of a wiring and the LTPS transistor be used as a transistor for controlling current.

One of the transistors provided in the first pixel circuit (first transistor) functions as a transistor for transferring charge generated in the light-receiving element. One of a source and a drain of the transistor is electrically connected to the pixel electrode of the light-receiving element.

One of the transistors provided in the second pixel circuit (second transistor) functions as a transistor for controlling current flowing through the light-emitting element. One of a source and a drain of the transistor is electrically connected to the pixel electrode of the light-emitting element.

Here, LTPS transistors are preferably used as the first transistor and the second transistor. This structure can shorten a time taken for charge transfer in the first pixel circuit. In addition, current flowing through the light-emitting element in the second pixel circuit can be increased.

Alternatively, it is preferable that an OS transistor be used as the first transistor and an LTPS transistor be used as the second transistor. This structure enables a reduction in leakage current between the light-receiving element and a holding node in the first pixel circuit, and capture of a high-quality image with low noise. In addition, charge can be held in the holding node for a long period, so that global shutter driving can be achieved. Moreover, current flowing through the light-emitting element in the second pixel circuit can be increased.

More specific structure examples are described below with reference to drawings.

### Structure Example of Display Device

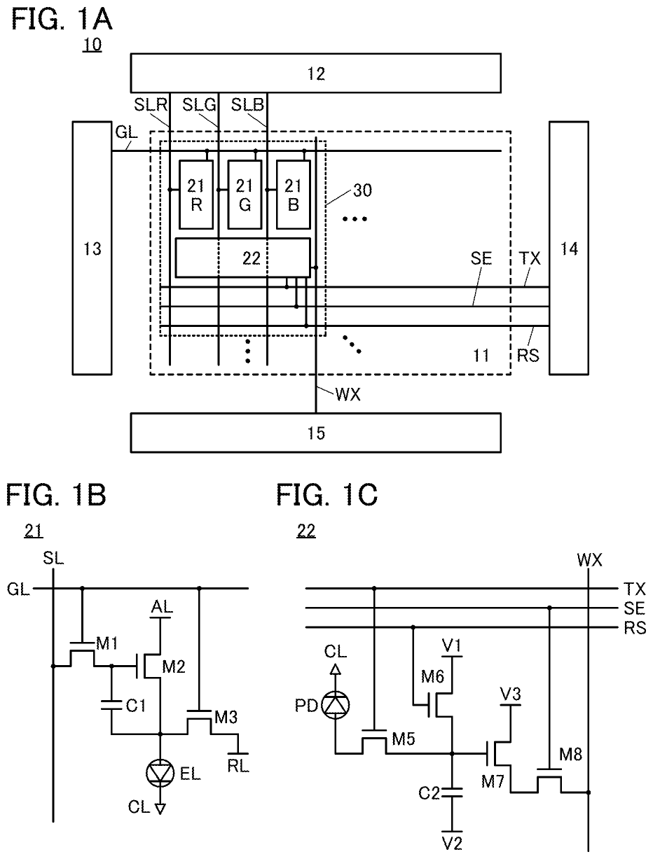

FIG. 1A is a block diagram of a display device 10. The display device 10 includes a display portion 11, a driver circuit portion 12, a driver circuit portion 13, a driver circuit portion 14, a circuit portion 15, and the like.

The display portion 11 includes a plurality of pixels 30 arranged in a matrix. The pixels 30 each include a subpixel 21R, a subpixel 21G, a subpixel 21B, and an imaging pixel 22. The subpixel 21R, the subpixel 21G, and the subpixel 21B each include a light-emitting element functioning as a display element. The imaging pixel 22 includes a light-receiving element functioning as a photoelectric conversion element.

The pixel 30 is electrically connected to a wiring GL, a wiring SLR, a wiring SLG, a wiring SLB, a wiring TX, a wiring, SE, a wiring RS, a wiring WX, and the like. The wiring SLR, the wiring SLG, and the wiring SLB are electrically connected to the driver circuit portion 12. The wiring GL is electrically connected to the driver circuit portion 13. The driver circuit portion 12 functions as a source line driver circuit (also referred to as a source driver). The driver circuit portion 13 functions as a gate line driver circuit (also referred to as a gate driver).

The pixels 30 each include the subpixel 21R, the subpixel 21G, and the subpixel 21B. For example, the subpixel 21R exhibits a red color, the subpixel 21G exhibits a green color, and the subpixel 21B exhibits a blue color. Thus, the display device 10 can perform full-color display. Note that although the example where the pixels 30 each include subpixels of three colors is shown here, subpixels of four or more colors may be included.

The subpixel 21R includes a light-emitting element emitting red light. The subpixel 21G includes a light-emitting element emitting green light. The subpixel 21B includes a light-emitting element emitting blue light. Note that the pixel 30 may include a subpixel including a light-emitting element emitting light of another color. For example, the pixel 30 may include, in addition to the three subpixels, a subpixel including a light-emitting element emitting white light or a subpixel including a light-emitting element emitting yellow light.

The wiring GL is electrically connected to the subpixel 21R, the subpixel 21G, and the subpixel 21B arranged in a row direction (an extending direction of the wiring GL). The wiring SLR, the wiring SLG, and the wiring SLB are electrically connected to the subpixels 21R, the subpixels 21G, and the subpixels 21B arranged in a column direction (an extending direction of the wiring SLR), respectively.

The imaging pixel 22 included in the pixel 30 is electrically connected to the wiring TX, the wiring SE, the wiring RS, and the wiring WX. The wiring TX, the wiring SE, and the wiring RS are electrically connected to the driver circuit portion 14, and the wiring WX is electrically connected to the circuit portion 15.

The driver circuit portion 14 has a function of generating a signal for driving the imaging pixel 22 and outputting the signal to the imaging pixel 22 through the wiring SE, the wiring TX, and the wiring RS. The circuit portion 15 has a function of receiving a signal output from the imaging pixel 22 through the wiring WX and outputting the signal to the outside as image data. The circuit portion 15 functions as a read circuit.

### Structure Example 1 of Pixel Circuit

FIG. 1B illustrates an example of a circuit diagram of a pixel 21 that can be used as the subpixel 21R, the subpixel 21G, and the subpixel 21B. The pixel 21 includes a transistor M1, a transistor M2, a transistor M3, a capacitor C1, and a light-emitting element EL. A wiring GL and a wiring SL are electrically connected to the pixel 21. The wiring SL corresponds to any of the wiring SLR, the wiring SLG, and the wiring SLB illustrated in FIG. 1A.

A gate of the transistor M1 is electrically connected to the wiring GL, one of a source and a drain of the transistor M1 is electrically connected to the wiring SL, and the other of the source and the drain of the transistor M1 is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting element EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting element EL is electrically connected to a wiring CL.

The transistor M1 and the transistor M3 function as switches. The transistor M2 functions as a transistor for controlling current flowing through the light-emitting element EL.

Here, it is preferable to use LTPS transistors as all of the transistors M1 to M3. Alternatively, it is preferable to use OS transistors as the transistor M1 and the transistor M3 and to use an LTPS transistor as the transistor M2.

A transistor in which an oxide semiconductor is used for a semiconductor layer where a channel is formed can be used as the OS transistor. The semiconductor layer preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Further alternatively, it is preferable to use an oxide containing indium, gallium, tin, and zinc.

A transistor using an oxide semiconductor having a wider band gap and a lower carrier density than silicon can achieve an extremely low off-state current. Such a low off-state current enables long-period holding of charge accumulated in a capacitor that is connected in series to the transistor. Therefore, it is particularly preferable to use a transistor containing an oxide semiconductor as each of the transistors M1 and M3 connected in series to the capacitor C1. The use of the transistor containing an oxide semiconductor as each of the transistors M1 and M3 can prevent leakage of charge held in the capacitor C1 through the transistor M1 or the transistor M3. Furthermore, since charge held in the capacitor C1 can be held for a long period, a still image can be displayed for a long period without rewriting data in the pixel 21.

A data potential D is supplied to the wiring SL. A selection signal is supplied to the wiring GL. The selection signal includes a potential for turning on a transistor and a potential for turning off the transistor.

A reset potential is supplied to the wiring RL. An anode potential is supplied to the wiring AL. A cathode potential is supplied to the wiring CL. In the pixel 21, the anode potential is higher than the cathode potential. The reset potential supplied to the wiring RL can be set such that a potential difference between the reset potential and the cathode potential is lower than the threshold voltage of the light-emitting element EL. The reset potential can be a potential higher than the cathode potential, a potential equal to the cathode potential, or a potential lower than the cathode potential.

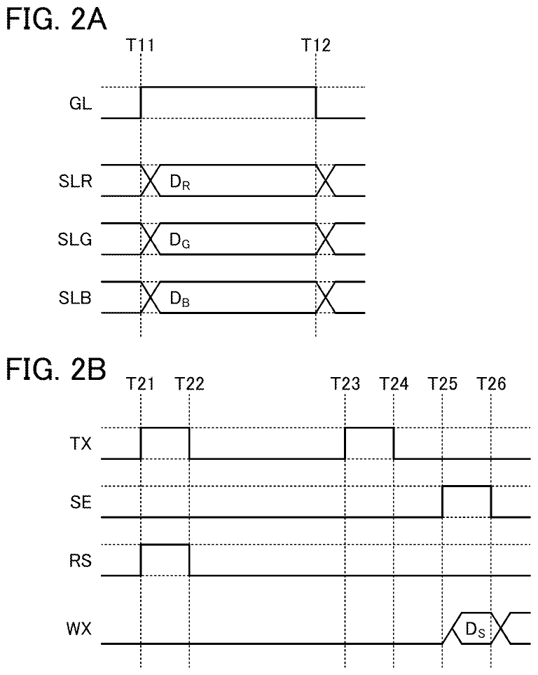

An example of a driving method of the case where the structure of the pixel 21 is applied to each of the subpixels 21R, 21G, and 21B illustrated in FIG. 1A is described with reference to a timing chart in FIG. 2A. FIG. 2A shows examples of signals input to the wiring GL, the wiring SLR, the wiring SLG, and the wiring SLB.

### <Before Time T11>

Before Time T11, the subpixel 21R, the subpixel 21G, and the subpixel 21B are in the non-selected state. Before time T11, a potential for turning off the transistor M1 and the transistor M3 (here, a low-level potential) is supplied to the wiring GL.

### <Period T11-T12>

A period from Time T11 to Time T12 corresponds to a period in which data is written to a pixel. At Time T11, a potential for turning on the transistor M1 and the transistor M3 (here, a high-level potential) is supplied to the wiring GL, and a data potential D_{R}, a data potential D_{G}, and a data potential DB are supplied to the wiring SLR, the wiring SLG, and the wiring SLB, respectively. At this time, the transistor M1 is turned on, and the data potential is supplied to the gate of the transistor M2 from the wiring SLR, the wiring SLG, or the wiring SLB. In addition, the transistor M3 is turned on, and the reset potential is supplied to the one electrode of the light-emitting element EL from the wiring RL. Thus, light emission from the light-emitting element EL can be prevented during the writing period.

### <After Time T12>

A period after Time T12 corresponds to a period in which data is written to the next row. At Time T12, a potential for turning off the transistor M1 and the transistor M3 is supplied to the wiring GL, and the transistor M1 and the transistor M3 are turned off. Thus, current corresponding to the gate potential of the transistor M2 flows through the light-emitting element EL, so that the light-emitting element EL emits light with desired luminance.

The above is the description of the example of the method for driving the pixel 21.

### Structure Example 2 of Pixel Circuit

FIG. 1C illustrates an example of a circuit diagram of the imaging pixel 22. The imaging pixel 22 includes a transistor M5, a transistor M6, a transistor M7, a transistor M8, a capacitor C2, and a light-receiving element PD.

A gate of the transistor M5 is electrically connected to the wiring TX, one of a source and a drain of the transistor M5 is electrically connected to an anode electrode of the light-receiving element PD, and the other of the source and the drain of the transistor M5 is electrically connected to one of a source and a drain of the transistor M6, a first electrode of the capacitor C2, and a gate of the transistor M7. A gate of the transistor M6 is electrically connected to the wiring RS, and the other of the source and the drain of the transistor M6 is electrically connected to a wiring V1. One of a source and a drain of the transistor M7 is electrically connected to a wiring V3, and the other of the source and the drain of the transistor M7 is electrically connected to one of a source and a drain of the transistor M8. A gate of the transistor M8 is electrically connected to the wiring SE, and the other of the source and the drain of the transistor M8 is electrically connected to the wiring WX. A cathode electrode of the light-receiving element PD is electrically connected to the wiring CL. A second electrode of the capacitor C2 is electrically connected to a wiring V2.

The transistor M5, the transistor M6, and the transistor M8 function as switches. The transistor M7 functions as an amplifier element (an amplifier).

It is preferable to use LTPS transistors as all of the transistors M5 to M8. Alternatively, it is preferable to use OS transistors as the transistor M5 and the transistor M6 and to use an LTPS transistor as the transistor M7. In that case, the transistor M8 may be either an OS transistor or an LTPS transistor.

By using the OS transistors as the transistor M5 and the transistor M6, a potential held in the gate of the transistor M7 on the basis of charge generated in the light-receiving element PD can be prevented from leaking through the transistor M5 or the transistor M6.

For example, in the case where an image is captured using a global shutter system, a period from the end of charge transfer operation to the start of read operation (charge holding period) varies among pixels. When an image having the same grayscale level in all the pixels is captured, output signals in all the pixels ideally have potentials of the same level. However, in the case where the length of the charge holding period varies row by row, if charge accumulated at nodes in the pixels in each row leaks out over time, the potential of an output signal in a pixel varies row by row, and image data varies in grayscale level row by row. Thus, when the OS transistors are used as the transistor M5 and the transistor M6, such a potential change at the node in the pixel can be extremely small. That is, even when an image is captured using the global shutter system, it is possible to suppress variation in grayscale level of image data due to a difference in the length of the charge holding period, and it is possible to enhance the quality of captured images.

Meanwhile, it is preferable to use, as the transistor M7, an LTPS transistor containing low-temperature polysilicon in a semiconductor layer. The LTPS transistor can have a higher field-effect mobility than the OS transistor, and has excellent drive capability and current capability. Thus, the transistor M7 can operate at higher speed than the transistor M5 and the transistor M6. By using the LTPS transistor as the transistor M7, an output in accordance with the extremely low potential based on the amount of light received by the light-receiving element PD can be quickly supplied to the transistor M8.

In other words, in the imaging pixel 22, the transistor M5 and the transistor M6 have low leakage current and the transistor M7 has high drive capability, whereby, when the light-receiving element PD receives light, the charge transferred through the transistor M5 can be held without leakage and high-speed reading can be performed.

Low off-state current, high-speed operation, and the like, which are required for the transistors M5 to M7, are not necessarily required for the transistor M8, which functions as a switch for supplying the output from the transistor M7 to the wiring WX. For this reason, either low-temperature polysilicon or an oxide semiconductor may be used for the semiconductor layer of the transistor M8.

Although n-channel transistors are shown in FIG. 1B and FIG. 1C, p-channel transistors can alternatively be used.

The transistors included in the pixel 21 and the imaging pixel 22 are preferably arranged over the same substrate.

An example of a method for driving the imaging pixel 22 shown in FIG. 1C is described with reference to a timing chart in FIG. 2B. FIG. 2B shows signals input to the wiring TX, the wiring SE, the wiring RS, and the wiring WX.

### <Before Time T21>

Before Time T21, a low-level potential is supplied to the wiring TX, the wiring SE, and the wiring RS. Data is not output to the wiring WX, and the wiring WX is regarded as being set to a low-level potential here. Note that a predetermined potential may be supplied to the wiring WX.

### <Period T21-T22>

At Time T21, a potential for turning on a transistor (here, a high-level potential) is supplied to the wiring TX and the wiring RS. In addition, a potential for turning off a transistor (here, a low-level potential) is supplied to the wiring SE.

At this time, the transistor M5 and the transistor M6 are turned on, so that a potential lower than the potential of the cathode electrode of the light-receiving element PD is supplied to the anode electrode of the light-receiving element PD from the wiring V1 through the transistor M6 and the transistor M5. That is, reverse bias voltage is applied to the light-receiving element PD.

In addition, the potential of the wiring V1 is also supplied to the first electrode of the capacitor C2, so that charge is stored in the capacitor C2.

Period T21-T22 can also be referred to as a reset (initialization) period.

### <Period T22-T23>

At Time T22, a low-level potential is supplied to the wiring TX and the wiring RS. Thus, the transistor M5 and the transistor M6 are turned off.

The transistor M5 is turned off, so that the reverse bias voltage is retained in the light-receiving element PD. Here, photoelectric conversion is caused by incident light on the light-receiving element PD, and charge is accumulated in the anode electrode of the light-receiving element PD.

Period T22-T23 can also be referred to as an exposure period. The exposure period is set in accordance with the sensitivity of the light-receiving element PD, the amount of incident light, or the like and is preferably set to be much longer than at least the reset period.

In addition, in Period T22-T23, the transistor M5 and the transistor M6 are turned off, so that the potential of the first electrode of the capacitor C2 is held at a low-level potential supplied from the wiring V1.

### <Period T23-T24>

At Time T23, a high-level potential is supplied to the wiring TX. Thus, the transistor M5 is turned on, and the charge accumulated in the light-receiving element PD is transferred to the first electrode of the capacitor C2 through the transistor M5. Accordingly, the potential of a node to which the first electrode of the capacitor C2 is connected increases in accordance with the amount of the charge accumulated in the light-receiving element PD. Consequently, a potential corresponding to the amount of light to which the light-receiving element PD is exposed is supplied to the gate of the transistor M7.

### <Period T24-T25>

At Time T24, a low-level potential is supplied to the wiring TX. Thus, the transistor M5 is turned off, and a node to which the gate of the transistor M7 is connected is brought into a floating state. Since the light-receiving element PD is continuously exposed to light, a change in the potential of the node to which the gate of the transistor M7 is connected can be prevented by turning off the transistor M5 after the transfer operation in Period T23-T24 is completed.

### <Period T25-T26>

At Time T25, a high-level potential is supplied to the wiring SE. Thus, the transistor M8 is turned on. Period T25-T26 can also be referred to as a read period.

For example, a source follower circuit is composed of the transistor M7 and a transistor included in the circuit portion 15 so that data can be read. In that case, a data potential D_{S} output to the wiring WX is determined in accordance with a gate potential of the transistor M7. Specifically, a potential obtained by subtracting the threshold voltage of the transistor M7 from the gate potential of the transistor M7 is output to the wiring WX as the data potential D_{S}, and the potential is read by the read circuit included in the circuit portion 15.

Note that a source ground circuit is composed of the transistor M7 and the transistor included in the circuit portion 15 so that data can be read by the read circuit included in the circuit portion 15.

<At and after Time T26>

At Time T26, a low-level potential is supplied to the wiring SE. Thus, the transistor M8 is turned off. Accordingly, data reading in the imaging pixel 22 is completed. After Time T26, data reading operation is sequentially performed in the next rows.

When the driving method shown in FIG. 2B is used, the exposure period and the read period can be set independently; therefore, light exposure can be concurrently performed on all the imaging pixels 22 in the display portion 11, and then data can be sequentially read. Accordingly, what is called global shutter driving can be achieved. In the case of performing global shutter driving, a transistor including an oxide semiconductor, which has an extremely low leakage current in an off-state, is preferably used as a transistor functioning as a switch in the imaging pixel 22 (in particular, each of the transistors M5 and M6).

The above is the description of the example of the method for driving the imaging pixel 22.

### Modification Example of Pixel Circuit

Structure examples of the pixel 21 and the imaging pixel 22, which are different from the above, are described below.

Transistors each including a pair of gates overlapping with each other with a semiconductor layer therebetween can be used as the transistors included in the pixel 21 and the imaging pixel 22. Specific examples of an LTPS transistor including a pair of gates and an OS transistor including a pair of gates are described in detail below.

In the transistor including a pair of gates, the same potential is supplied to the pair of gates electrically connected to each other, whereby on-state current of the transistor can be increased and the saturation characteristics can be improved. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

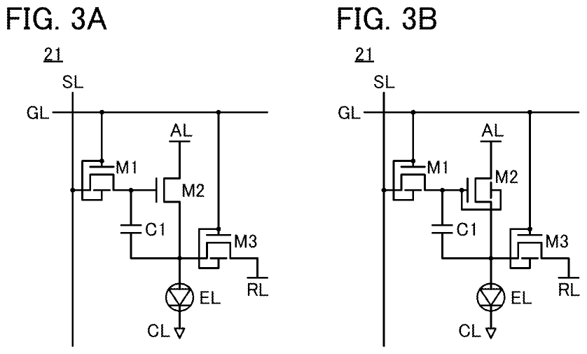

The pixel 21 in FIG. 3A is an example in which a transistor having a pair of gates is used as each of the transistors M1 and M3. The gates are electrically connected to each other in each of the transistors M1 and M3. Such a structure makes it possible to shorten the period in which data is written to the pixel 21.

The pixel 21 in FIG. 3B is an example in which a transistor including a pair of gates is used as the transistor M2 in addition to the transistors M1 and M3. The gates of the transistor M2 are electrically connected to each other. The transistor M2 having such a structure enables the saturation characteristics to be improved, whereby emission luminance of the light-emitting element EL can be controlled easily and the display quality can be increased.

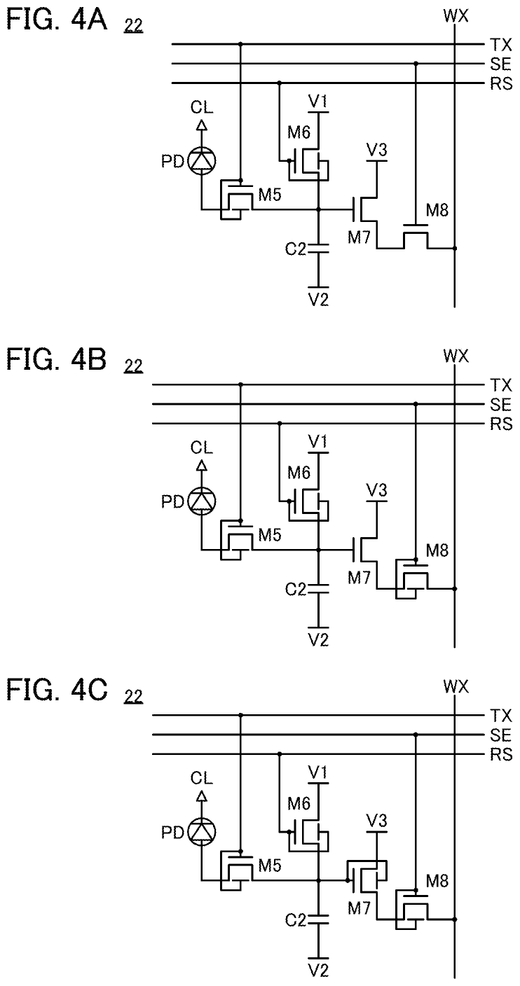

The imaging pixel 22 in FIG. 4A is an example in which a transistor having a pair of gates connected to each other is used as each of the transistors M5 and M6. Such a structure can shorten the time required for the reset operation and the transferring operation.

The imaging pixel 22 in FIG. 4B is an example in which a transistor having a pair of gates connected to each other is used as the transistor M8 in the structure illustrated in FIG. 4A. With such a structure, the time required for reading can be shortened.

The imaging pixel 22 in FIG. 4C is an example in which a transistor having a pair of gates connected to each other is used as the transistor M7 in the structure illustrated in FIG. 4B. With such a structure, the time required for reading can be further shortened.

### Cross-Sectional Structure Example of Display Device

Structure examples of a transistor, a light-receiving element, and a light-emitting element that can be used in the above display device will be described below.

### Structure Example 1

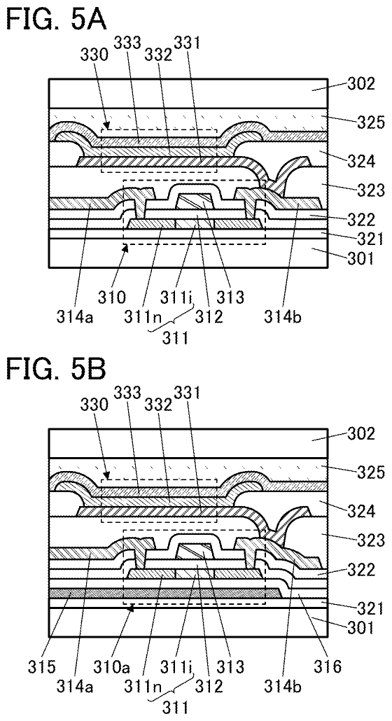

FIG. 5A is a schematic cross-sectional view including a transistor 310 and a light-emitting element 330.

The transistor 310 is a transistor containing polycrystalline silicon in its semiconductor layer. In the structure illustrated in FIG. 5A, the transistor 310 corresponds to the transistor M2 in the pixel 21, and the light-emitting element 330 corresponds to the light-emitting element EL, for example. In other words, FIG. 5A illustrates an example in which one of a source and a drain of the transistor 310 is electrically connected to a pixel electrode of the light-emitting element 330.

In FIG. 5A, the transistor 310 and the light-emitting element 330 are provided between a substrate 301 and a substrate 302.

The transistor 310 includes a semiconductor layer 311, an insulating layer 312, a conductive layer 313, and the like. The semiconductor layer 311 includes a channel formation region 311i and low-resistance regions 311n. The semiconductor layer 311 contains silicon. The semiconductor layer 311 preferably contains polycrystalline silicon. Part of the insulating layer 312 functions as a gate insulating layer. Part of the conductive layer 313 functions as a gate electrode.

The low-resistance regions 311n contain an impurity element. For example, in the case where the transistor 310 is an n-channel transistor, phosphorus, arsenic, or the like is added to the low-resistance regions 311n. In the case where the transistor 310 is a p-channel transistor, boron, aluminum, or the like is added to the low-resistance regions 311n. In addition, in order to control the threshold voltage of the transistor 310, the above-described impurity may be added to the channel formation region 311i.

An insulating layer 321 is provided over the substrate 301. The semiconductor layer 311 is provided over the insulating layer 321. The insulating layer 312 is provided to cover the semiconductor layer 311 and the insulating layer 321. The conductive layer 313 is provided over the insulating layer 312 to overlap with the semiconductor layer 311.

An insulating layer 322 is provided to cover the conductive layer 313 and the insulating layer 312. A conductive layer 314a and a conductive layer 314b are provided over the insulating layer 322. The conductive layer 314a and the conductive layer 314b are electrically connected to the low-resistance regions 311n in openings provided in the insulating layer 322 and the insulating layer 312. Part of the conductive layer 314a functions as one of a source electrode and a drain electrode, and part of the conductive layer 314b functions as the other of the source electrode and the drain electrode. An insulating layer 323 is provided to cover the conductive layer 314a, the conductive layer 314b, and the insulating layer 322.

The light-emitting element 330 includes a conductive layer 331, a light-emitting layer 332, and a conductive layer 333 from the substrate 301 side. The conductive layer 331 functions as the pixel electrode. The conductive layer 333 functions as a common electrode.

The conductive layer 331 is provided over the insulating layer 323. The conductive layer 331 is electrically connected to the conductive layer 314b through an opening provided in the insulating layer 323. An insulating layer 324 is provided to cover an end portion of the conductive layer 331 and the opening. The light-emitting layer 332 is provided to cover part of the conductive layer 331 and part of the insulating layer 324. The conductive layer 333 is provided to cover the light-emitting layer 332 and the insulating layer 324.

An adhesive layer 325 is provided over the conductive layer 333, and the substrate 301 and the substrate 302 are bonded to each other with the adhesive layer 325.

### Structure Example 2

FIG. 5B illustrates a transistor 310a including a pair of gate electrodes. The transistor 310a in FIG. 5B is different from the transistor 310 in FIG. 5A mainly in that a conductive layer 315 and an insulating layer 316 are provided.

The conductive layer 315 is provided over the insulating layer 321. The insulating layer 316 is provided to cover the conductive layer 315 and the insulating layer 321. The semiconductor layer 311 is provided such that at least the channel formation region 311i overlaps with the conductive layer 315 with the insulating layer 316 therebetween.

In the transistor 310a in FIG. 5B, part of the conductive layer 313 functions as a first gate electrode, and part of the conductive layer 315 functions as a second gate electrode. In this case, part of the insulating layer 312 functions as a first gate insulating layer, and part of the insulating layer 316 functions as a second gate insulating layer.

In the case where the first gate electrode and the second gate electrode are electrically connected to each other, the conductive layer 313 and the conductive layer 315 are electrically connected to each other through an opening provided in the insulating layer 312 and the insulating layer 316. In the case where the second gate electrode is electrically connected to a source or a drain, the conductive layer 314a or the conductive layer 314b is electrically connected to the conductive layer 315 through an opening provided in the insulating layer 322, the insulating layer 312, and the insulating layer 316.

Note that in Structure example 1 and Structural example 2 described above, the case where the transistor 310 or the transistor 310a is electrically connected to the light-emitting element 330 is described. When the light-emitting element 330 is replaced with a light-receiving element, the transistor 310 or the transistor 310a can be electrically connected to the light-receiving element. This structure can be achieved when the light-emitting layer 332 included in the light-emitting element 330 is replaced with an active layer to be described later. In this case, one of the source and the drain of the transistor 310 or the transistor 310a is electrically connected to a pixel electrode of the light-receiving element. For example, the transistor M5 in the imaging pixel 22 in FIG. 1C or the like corresponds to the transistor 310 or the transistor 310a, and the light-receiving element PD in FIG. 1C or the like corresponds to the light-receiving element.

In the case where all of the transistors included in the pixel 21 and the imaging pixel 22 are LTPS transistors, the transistor 310 illustrated in FIG. 5A or the transistor 310a illustrated in FIG. 5B can be used. In that case, the transistors 310a each including a second gate may be used as all of the transistors included in the pixel 21 and the imaging pixel 22; the transistors 310 without a second gate may be used as all of the transistors; or the transistors 310a each including a second gate and the transistors 310 without a second gate may be used in combination.

### Structure Example 3

Described below is an example of a structure including both a transistor containing silicon in its semiconductor layer and a transistor containing a metal oxide in its semiconductor layer.

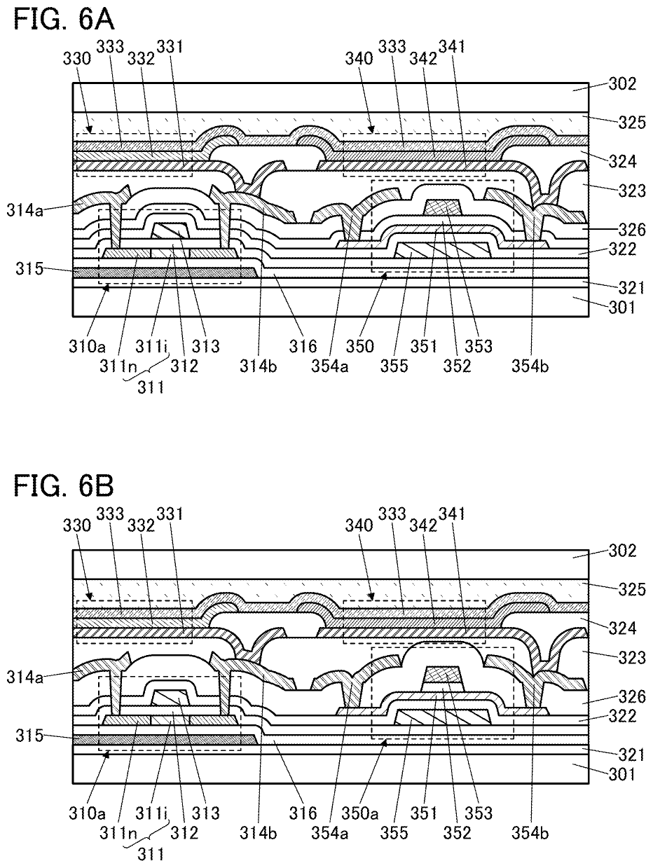

FIG. 6A is a schematic cross-sectional view including the transistor 310a, a transistor 350, the light-emitting element 330, and a light-receiving element 340.

Structure example 2 described above can be referred to for the transistor 310a and the light-emitting element 330.

The transistor 350 is a transistor containing a metal oxide in its semiconductor layer. In the structure illustrated in FIG. 6A, the transistor 350 corresponds to the transistor M5 in the imaging pixel 22, and the light-receiving element 340 corresponds to the light-receiving element PD, for example. In other words, FIG. 6A illustrates an example in which one of a source and a drain of the transistor 350 is electrically connected to a pixel electrode of the light-receiving element 340.

FIG. 6A illustrates an example in which the transistor 350 includes a pair of gates.

The transistor 350 includes a conductive layer 355, the insulating layer 322, a semiconductor layer 351, an insulating layer 352, a conductive layer 353, and the like. Part of the conductive layer 353 functions as a first gate of the transistor 350, and part of the conductive layer 355 functions as a second gate of the transistor 350. Part of the insulating layer 352 functions as a first gate insulating layer of the transistor 350, and part of the insulating layer 322 functions as a second gate insulating layer of the transistor 350.

The conductive layer 355 is provided over the insulating layer 312. The insulating layer 322 is provided to cover the conductive layer 355. The semiconductor layer 351 is provided over the insulating layer 322. The insulating layer 352 is provided to cover the semiconductor layer 351 and the insulating layer 322. The conductive layer 353 is provided over the insulating layer 352 and includes a region overlapping with the semiconductor layer 351 and the conductive layer 355.

An insulating layer 326 is provided to cover the insulating layer 352 and the conductive layer 353. A conductive layer 354a and a conductive layer 354b are provided over the insulating layer 326. The conductive layer 354a and the conductive layer 354b are electrically connected to the semiconductor layer 351 in openings provided in the insulating layer 326 and the insulating layer 352. Part of the conductive layer 354a functions as one of a source electrode and a drain electrode, and part of the conductive layer 354b functions as the other of the source electrode and the drain electrode. The insulating layer 323 is provided to cover the conductive layer 354a, the conductive layer 354b, and the insulating layer 326.

Here, the conductive layer 314a and the conductive layer 314b electrically connected to the transistor 310a are preferably formed by processing the same conductive film as the conductive layer 354a and the conductive layer 354b. In FIG. 6A, the conductive layer 314a, the conductive layer 314b, the conductive layer 354a, and the conductive layer 354b are formed on the same plane (i.e., in contact with the top surface of the insulating layer 326) and contain the same metal element. In this case, the conductive layer 314a and the conductive layer 314b are electrically connected to the low-resistance regions 311n through openings provided in the insulating layer 326, the insulating layer 352, the insulating layer 322, and the insulating layer 312. This is preferable because the manufacturing process can be simplified.

Moreover, the conductive layer 313 functioning as the first gate electrode of the transistor 310a and the conductive layer 355 functioning as the second gate electrode of the transistor 350 are preferably formed by processing the same conductive film. In FIG. 6A, the conductive layer 313 and the conductive layer 355 are formed on the same plane (i.e., in contact with the top surface of the insulating layer 312) and contain the same metal element. This is preferable because the manufacturing process can be simplified.

The light-receiving element 340 includes a conductive layer 341, an active layer 342, and the conductive layer 333.

The conductive layer 331 and the conductive layer 341 are provided over the insulating layer 323. The conductive layer 331 and the conductive layer 341 are preferably formed by processing the same conductive film. The conductive layer 341 is electrically connected to the conductive layer 354b through an opening formed in the insulating layer 323.

The insulating layer 324 is provided to cover an end portion of the conductive layer 341 and the opening. The active layer 342 is provided to cover part of the conductive layer 341 and part of the insulating layer 324.

The active layer 342 and the light-emitting layer 332 each have an island-shaped top surface. The conductive layer 333 functioning as a common electrode is provided to cover the light-emitting layer 332 and the active layer 342. The conductive layer 333 includes a portion overlapping with the conductive layer 331 with the light-emitting layer 332 therebetween and a portion overlapping with the conductive layer 341 with the active layer 342 therebetween.

In this manner, the pixel electrode of the light-emitting element 330 and the pixel electrode of the light-receiving element 340 are formed on the same plane, the light-emitting layer 332 and the active layer 342 are each formed to have an island shape, and the conductive layer 333 is used as the common electrode, so that the light-emitting element 330 and the light-receiving element 340 can be formed by separate formation of only the light-emitting layer 332 and the active layer 342. Thus, a highly functional display device can be manufactured at low cost.

In FIG. 6A, the insulating layer 352 functioning as the first gate insulating layer of the transistor 350 covers an end portion of the semiconductor layer 351; however, the insulating layer 352 may be processed to have substantially the same top surface shape as that of the conductive layer 353 as in the transistor 350a illustrated in FIG. 6B.

Note that in this specification and the like, the expression “having substantially the same top surface shapes” means that at least outlines of stacked layers partly overlap with each other. For example, the case of patterning or partly patterning an upper layer and a lower layer with the use of the same mask pattern is included in the expression. The expression “having substantially the same top surface shapes” also includes the case where the outlines do not completely overlap with each other; for instance, the edge of the upper layer may be positioned on the inner side or the outer side of the edge of the lower layer.

The above is the description of the cross-sectional structure examples of the display device.

At least part of this embodiment can be implemented in combination with any of the other embodiments described in this specification as appropriate.

### Embodiment 2

In this embodiment, a display device of one embodiment of the present invention is described. A display device described below includes a light-emitting element and a light-receiving element. The display device has a function of displaying an image, a function of performing position sensing with reflected light from an object to be sensed, and a function of capturing an image of a fingerprint or the like with reflected light from an object to be sensed. The display device described below can also be regarded to have a function of a touch panel and a function of a fingerprint sensor.

The display device of one embodiment of the present invention includes a light-emitting element emitting first light and a light-receiving element receiving the first light. That is, the light-receiving element is preferably a photoelectric conversion element whose light-receiving wavelength range covers an emission wavelength of the light-emitting element. As the first light, visible light or infrared light can be used. In the case where infrared light is used as the first light, in addition to the light-emitting element emitting the first light, a light-emitting element emitting visible light can be included.

In addition, the display device includes a pair of substrates (also referred to as a first substrate and a second substrate). The light-emitting element and the light-receiving element are positioned between the first substrate and the second substrate. The first substrate is positioned on a display surface side, and the second substrate is positioned on a side opposite to the display surface side. A sealing substrate for sealing the light-emitting element, a protective film, or the like can be used for the first substrate. In addition, a resin layer may be provided between the first substrate and the second substrate to attach the first substrate and the second substrate to each other.

Visible light is emitted from the light-emitting element to the outside through the first substrate. A plurality of light-emitting elements arranged in a matrix are included in the display device, so that an image can be displayed.

The first light emitted from the light-emitting element reaches a surface of the first substrate. Here, when an object touches the surface of the first substrate, the first light is scattered at an interface between the first substrate and the object, and then part of the scattered light is incident on the light-receiving element. When the light-receiving element receives the first light, the light-receiving element can convert the first light into an electric signal in accordance with the intensity of the first light and output the electric signal. In the case where a plurality of light-receiving elements arranged in a matrix are included in the display device, positional data, shape, or the like of the object that touches the first substrate can be sensed. That is, the display device can function as an image sensor panel, a touch sensor panel, or the like.

Note that even in the case where the object does not touch the surface of the first substrate, the first light that has passed the first substrate is reflected or scattered in the surface of the object, and the reflected light or the scattered light is incident on the light-receiving element through the first substrate. Thus, the display device can also be used as a non-contact touch sensor panel (also referred to as a near-touch panel).

In the case where visible light is used as the first light, the first light used for image display can be used as a light source of a touch sensor. In that case, the light-emitting element has a function of a display element and a function of a light source, so that the structure of the display device can be simplified. In contrast, in the case where infrared light is used as the first light, a user does not perceive the infrared light, so that imaging or sensing can be performed by the light-receiving element without a reduction in visibility of a displayed image.

In the case where infrared light is used as the first light, near-infrared light is preferably included. In particular, near-infrared light having one or more peaks in the range of a wavelength of greater than or equal to 700 nm and less than or equal to 2500 nm can be favorably used. In particular, the use of light having one or more peaks in the range of a wavelength of greater than or equal to 750 nm and less than or equal to 1000 nm is preferable because it permits an extensive choice of a material used for an active layer of the light-receiving element.

When a fingertip touches a surface of the display device, an image of a fingerprint can be captured. The fingerprint has a projection and a depression. When a finger touches the first substrate, the first light is likely to be scattered by the projection of the fingerprint that touches the surface of the first substrate. Therefore, the intensity of scattered light that is incident on the light-receiving element overlapping with the projection of the fingerprint is high and the intensity of scattered light that is incident on the light-receiving element overlapping with the depression of the fingerprint is low. Accordingly, the image of the fingerprint can be captured. A device including the display device of one embodiment of the present invention can perform fingerprint authentication that is a kind of biological authentication by utilizing a captured fingerprint image.

In addition, the display device can also capture an image of a blood vessel, especially a vein of a finger, a hand, or the like. For example, light having a wavelength of 760 nm and its vicinity is not absorbed by reduced hemoglobin in the vein, so that the position of the vein can be sensed by making an image from reflected light from a palm, a finger, or the like that is received by the light-receiving element. A device including the display device of one embodiment of the present invention can perform vein authentication that is a kind of biological authentication by utilizing a captured vein image.

In addition, the device including the display device of one embodiment of the present invention can perform touch sensing, fingerprint authentication, and vein authentication at the same time. Thus, high-security biological authentication can be performed at low cost without increasing the number of components.

The light-receiving element is preferably an element capable of receiving visible light and infrared light. In that case, as the light-emitting element, both a light-emitting element emitting infrared light and a light-emitting element emitting visible light are preferably included. Accordingly, visible light is reflected by a user's finger and reflected light is received by the light-receiving element, so that an image of a fingerprint can be captured. Furthermore, an image of a shape of a vein can be captured with infrared light. Accordingly, both fingerprint authentication and vein authentication can be performed in one display device. Moreover, fingerprint imaging and vein imaging may be performed either at different timings or at the same time. In the case where fingerprint imaging and vein imaging are performed at the same time, image data including both data on a fingerprint and data on a vein shape can be obtained, so that biological authentication with higher accuracy can be achieved.

Alternatively, the display device of one embodiment of the present invention may have a function of sensing a user's health condition. For example, by utilizing changes in reflectance and transmittance with respect to visible light and infrared light in accordance with a change in blood oxygen saturation and obtaining a time change in the oxygen saturation, a heart rate can be measured. Furthermore, a glucose concentration in the dermis, a neutral fats concentration in the blood, or the like can also be measured using infrared light or visible light. The device including the display device of one embodiment of the present invention can be used as a health care device capable of obtaining index data on a user's health condition.

More specific examples are described below with reference to drawings.

### Structure Example 1 of Display Panel

### Structure Example 1-1

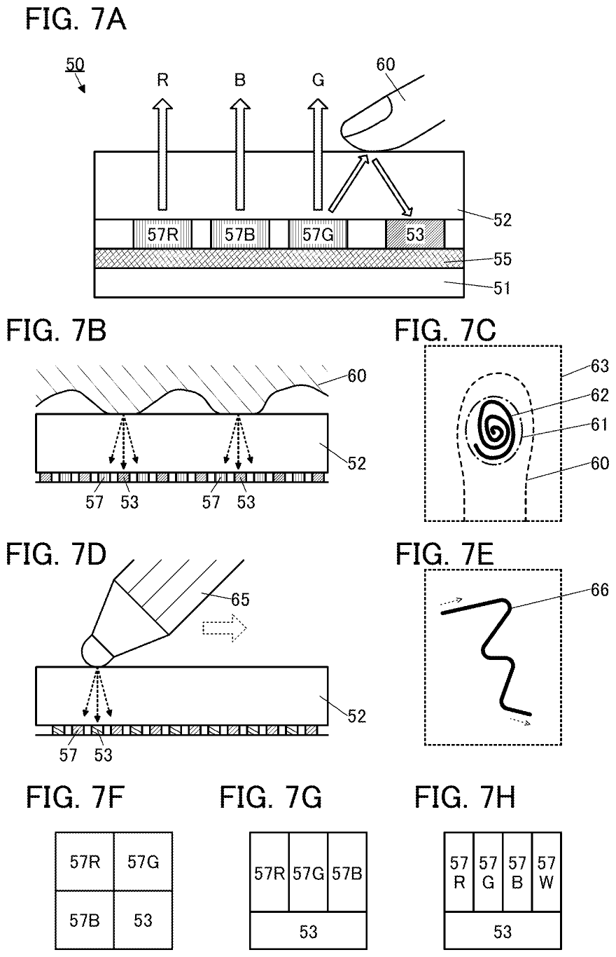

FIG. 7A is a schematic diagram of a display panel 50. The display panel 50 includes a substrate 51, a substrate 52, a light-receiving element 53, a light-emitting element 57R, a light-emitting element 57G, a light-emitting element 57B, a functional layer 55, and the like. The light-emitting elements 57R, 57G, and 57B and the light-receiving element 53 are provided between the substrate 51 and the substrate 52.

The light-emitting element 57R, the light-emitting element 57G, and the light-emitting element 57B emit red (R) light, green (G) light, and blue (B) light, respectively.

The display panel 50 includes a plurality of pixels arranged in a matrix. One pixel includes at least one subpixel. One subpixel includes one light-emitting element. For example, the pixel can include three subpixels (e.g., three colors of R, G, and B or three colors of yellow (Y), cyan (C), and magenta (M)) or four subpixels (e.g., four colors of R, G, B, and white (W) or four colors of R, G, B, and Y). The pixel further includes the light-receiving element 53. The light-receiving element 53 may be provided in all the pixels or in some of the pixels. In addition, one pixel may include a plurality of light-receiving elements 53.

FIG. 7A shows a state where a finger 60 touches a surface of the substrate 52. Part of light emitted from the light-emitting element 57G is reflected or scattered by a contact portion of the substrate 52 and the finger 60. In the case where part of reflected light or scattered light is incident on the light-receiving element 53, the contact of the finger 60 with the substrate 52 can be sensed. That is, the display panel 50 can function as a touch panel.

The functional layer 55 includes a circuit for driving the light-emitting elements 57R, 57G, and 57B, and a circuit for driving the light-receiving element 53. The functional layer 55 includes a switch, a transistor, a capacitor, a wiring, and the like. Note that in the case where the light-emitting elements 57R, 57G, and 57B and the light-receiving element 53 are driven by a passive-matrix method, the functional layer 55 does not necessarily include a switch and a transistor.

The display panel 50 may have a function of sensing a fingerprint of the finger 60. FIG. 7B schematically shows an enlarged view of the contact portion when the finger 60 touches the substrate 52. FIG. 7B shows light-emitting elements 57 and the light-receiving elements 53 that are alternately arranged.

The fingerprint of the finger 60 is formed of depressions and projections. Therefore, as shown in FIG. 7B, the projections of the fingerprint touch the substrate 52, and scattered light (indicated by dashed arrows) occurs on surfaces where the projections of the fingerprint touch the substrate 52.

As shown in FIG. 7B, in the intensity distribution of the scattered light on the surface where the finger 60 touches the substrate 52, the intensity of light almost perpendicular to the contact surface is the highest, and the intensity of light becomes lower as an angle becomes larger in an oblique direction. Thus, the intensity of light received by the light-receiving element 53 positioned directly below the contact surface (i.e., positioned in a portion overlapping with the contact surface) is the highest. Scattered light at greater than or equal to a predetermined scattering angle is fully reflected in the other surface (a surface opposite to the contact surface) of the substrate 52 and does not pass through the light-receiving element 53. As a result, a clear fingerprint image can be captured.

In the case where an arrangement interval between the light-receiving elements 53 is smaller than a distance between two projections of the fingerprint, preferably a distance between a depression and a projection adjacent to each other, a clear fingerprint image can be obtained. A distance between a depression and a projection of a human's fingerprint is approximately 200 μm; thus, the arrangement interval between the light-receiving elements 53 is, for example, less than or equal to 400 μm, preferably less than or equal to 200 μm, further preferably less than or equal to 150 μm, still further preferably less than or equal to 100 μm, even still further preferably less than or equal to 50 μm and greater than or equal to 1 μm, preferably greater than or equal to 10 μm, further preferably greater than or equal to 20 μm.

FIG. 7C shows an example of a fingerprint image captured with the display panel 50. In FIG. 7C, in an imaging range 63, the outline of the finger 60 is indicated by a dashed line and the outline of a contact portion 61 is indicated by a dashed-dotted line. In the contact portion 61, a high-contrast image of a fingerprint 62 can be captured by a difference in light incident on the light-receiving element 53.

The display panel 50 can also function as a touch panel or a pen tablet. FIG. 7D shows a state in which a tip of a stylus 65 slides in a direction indicated by a dashed arrow while the tip of the stylus 65 touches the substrate 52.

As shown in FIG. 7D, when light scattered by the contact surface of the tip of the stylus 65 and the substrate 52 is incident on the light-receiving element 53 that overlaps with the contact surface, the position of the tip of the stylus 65 can be sensed with high accuracy.

FIG. 7E shows an example of a path 66 of the stylus 65 that is sensed by the display panel 50. The display panel 50 can sense the position of an object to be sensed, such as the stylus 65, with high accuracy, so that high-definition drawing can be performed using a drawing application or the like. Unlike the case of using a capacitive touch sensor, an electromagnetic induction touch pen, or the like, the display panel 50 can sense even the position of a highly insulating object to be sensed, the material of a tip portion of the stylus 65 is not limited, and a variety of writing materials (e.g., a brush, a glass pen, a quill pen, and the like) can be used.

Here, FIGS. 7F to 7H show examples of pixels that can be used for the display panel 50.

Pixels shown in FIGS. 7F and 7G each include the light-emitting elements 57R, 57G, and 57B and the light-receiving element 53. The pixels each include a pixel circuit for driving the light-emitting elements 57R, 57G, and 57B and the light-receiving element 53.

FIG. 7F shows an example in which three light-emitting elements and one light-receiving element are arranged in a matrix of 2×2. FIG. 7G shows an example in which three light-emitting elements are arranged in one line and one laterally long light-receiving element 53 is provided below the three light-emitting elements.

The pixel shown in FIG. 7H includes a light-emitting element 57W for white (W).

Here, four light-emitting elements are arranged in one line and the light-receiving element 53 is provided below the four light-emitting elements.

Note that the pixel structure is not limited to the above structure, and a variety of pixel arrangements can be employed.

### Structure Example 1-2

An example of a structure including a light-emitting element emitting visible light, a light-emitting element emitting infrared light, and a light-receiving element is described below.

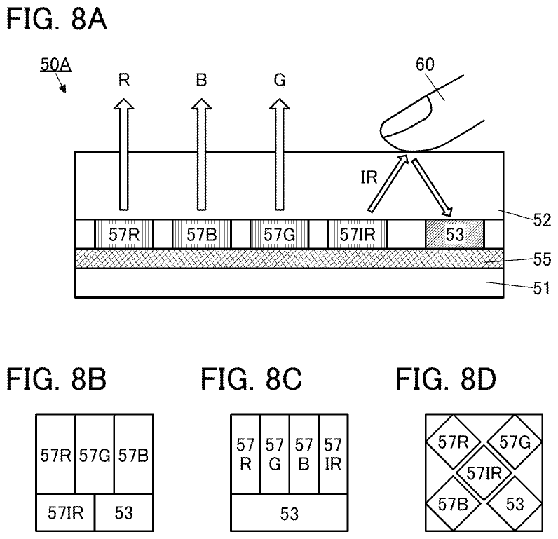

A display panel 50A shown in FIG. 8A includes a light-emitting element 5718 in addition to the components shown in FIG. 7A. The light-emitting element 571R is a light-emitting element emitting infrared light IR. Moreover, in that case, an element capable of receiving at least the infrared light IR emitted from the light-emitting element 571R is preferably used as the light-receiving element 53. As the light-receiving element 53, an element capable of receiving visible light and infrared light is further preferably used.

As shown in FIG. 8A, when the finger 60 touches the substrate 52, the infrared light IR emitted from the light-emitting element 5718 is reflected or scattered by the finger 60 and part of reflected light or scattered light is incident on the light-receiving element 53, so that the positional information of the finger 60 can be obtained.

FIGS. 8B to 8D show examples of pixels that can be used for the display panel 50A.

FIG. 8B shows an example in which three light-emitting elements are arranged in one line and the light-emitting element 571R and the light-receiving element 53 are arranged below the three light-emitting elements in a horizontal direction. FIG. 8C shows an example in which four light-emitting elements including the light-emitting element 571R are arranged in one line and the light-receiving element 53 is provided below the four light-emitting elements.

FIG. 8D shows an example in which three light-emitting elements and the light-receiving element 53 are arranged in all directions with the light-emitting element 571R used as a center.

Note that in the pixels shown in FIGS. 8B to 8D, the positions of the light-emitting elements can be interchangeable, or the positions of the light-emitting element and the light-receiving element can be interchangeable.

### Structure Example 2 of Display Panel

### Structure Example 2-1

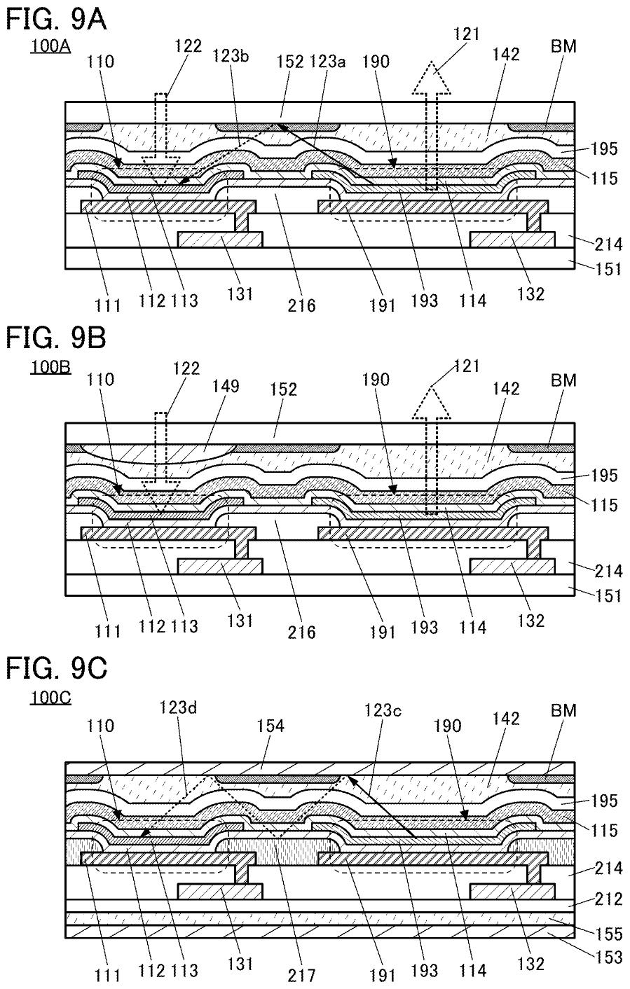

FIG. 9A is a schematic cross-sectional view of a display panel 100A.

The display panel 100A includes a light-receiving element 110, a light-emitting element 190, a transistor 131, a transistor 132, and the like between a pair of substrates (a substrate 151 and a substrate 152).

As the transistor 131 and the transistor 132, the transistor 310, the transistor 350, or the like described in Embodiment 1 can be used.

The light-receiving element 110 includes a pixel electrode 111, a common layer 112, an active layer 113, a common layer 114, and a common electrode 115. The light-emitting element 190 includes a pixel electrode 191, the common layer 112, a light-emitting layer 193, the common layer 114, and the common electrode 115.

The pixel electrode 111, the pixel electrode 191, the common layer 112, the active layer 113, the light-emitting layer 193, the common layer 114, and the common electrode 115 may each have a single-layer structure or a stacked-layer structure.

The pixel electrode 111 and the pixel electrode 191 are positioned over an insulating layer 214. The pixel electrode 111 and the pixel electrode 191 can be formed using the same material in the same step.

The common layer 112 is positioned over the pixel electrode 111 and the pixel electrode 191. The common layer 112 is shared by the light-receiving element 110 and the light-emitting element 190.

The active layer 113 overlaps with the pixel electrode 111 with the common layer 112 therebetween. The light-emitting layer 193 overlaps with the pixel electrode 191 with the common layer 112 therebetween. The active layer 113 contains a first organic compound, and the light-emitting layer 193 contains a second organic compound that is different from the first organic compound.

The common layer 114 is positioned over the common layer 112, the active layer 113, and the light-emitting layer 193. The common layer 114 is shared by the light-receiving element 110 and the light-emitting element 190.

The common electrode 115 includes a portion overlapping with the pixel electrode 111 with the common layer 112, the active layer 113, and the common layer 114 therebetween. The common electrode 115 further includes a portion overlapping with the pixel electrode 191 with the common layer 112, the light-emitting layer 193, and the common layer 114 therebetween. The common electrode 115 is shared by the light-receiving element 110 and the light-emitting element 190.

In the display panel of this embodiment, an organic compound is used for the active layer 113 of the light-receiving element 110. In the light-receiving element 110, the layers other than the active layer 113 can be common to the layers in the light-emitting element 190 (the EL element). Therefore, the light-receiving element 110 can be formed concurrently with the formation of the light-emitting element 190 only by adding a step of depositing the active layer 113 in the manufacturing process of the light-emitting element 190. The light-emitting element 190 and the light-receiving element 110 can be formed over one substrate. Accordingly, the light-receiving element 110 can be incorporated in the display panel without a significant increase in the number of manufacturing steps.

The display panel 100A shows an example in which the light-receiving element 110 and the light-emitting element 190 have a common structure except that the active layer 113 of the light-receiving element 110 and the light-emitting layer 193 of the light-emitting element 190 are separately formed. Note that the structures of the light-receiving element 110 and the light-emitting element 190 are not limited thereto. The light-receiving element 110 and the light-emitting element 190 may include separately formed layers other than the active layer 113 and the light-emitting layer 193 (see display panels 100D, 100E, and 100F to be described later). The light-receiving element 110 and the light-emitting element 190 preferably include at least one layer used in common (common layer). Thus, the light-receiving element 110 can be incorporated in the display panel without a significant increase in the number of manufacturing steps.

In the light-receiving element 110, the common layer 112, the active layer 113, and the common layer 114 that are positioned between the pixel electrode 111 and the common electrode 115 can each be referred to as an organic layer (a layer containing an organic compound). The pixel electrode 111 preferably has a function of reflecting visible light. An end portion of the pixel electrode 111 is covered with a partition 216. The common electrode 115 has a function of transmitting visible light.

The light-receiving element 110 has a function of sensing light. Specifically, the light-receiving element 110 is a photoelectric conversion element that receives light 122 entering from the outside through the substrate 152 and converts the light 122 into an electrical signal.

A light-blocking layer BM is provided on a surface of the substrate 152 on the substrate 151 side. The light-blocking layer BM has an opening at a position overlapping with the light-receiving element 110 and an opening at a position overlapping with the light-emitting element 190. Providing the light-blocking layer BM can control the range where the light-receiving element 110 senses light.

For the light-blocking layer BM, a material that blocks light emitted from the light-emitting element can be used. The light-blocking layer BM preferably absorbs visible light. As the light-blocking layer BM, a black matrix can be formed using a metal material or a resin material containing pigment (e.g., carbon black) or dye, for example. The light-blocking layer BM may have a stacked-layer structure of a red color filter, a green color filter, and a blue color filter.

Here, part of light emitted from the light-emitting element 190 is reflected in the display panel 100A and is incident on the light-receiving element 110 in some cases. The light-blocking layer BM can reduce the influence of such stray light. For example, in the case where the light-blocking layer BM is not provided, light 123a emitted from the light-emitting element 190 is reflected by the substrate 152 and reflected light 123b is incident on the light-receiving element 110 in some cases. Providing the light-blocking layer BM can inhibit entry of the reflected light 123b into the light-receiving element 110. Consequently, noise can be reduced, and the sensitivity of a sensor using the light-receiving element 110 can be increased.

In the light-emitting element 190, the common layer 112, the light-emitting layer 193, and the common layer 114 that are positioned between the pixel electrode 191 and the common electrode 115 can each be referred to as an EL layer. The pixel electrode 191 preferably has a function of reflecting visible light. An end portion of the pixel electrode 191 is covered with the partition 216. The pixel electrode 111 and the pixel electrode 191 are electrically insulated from each other by the partition 216. The common electrode 115 has a function of transmitting visible light.

The light-emitting element 190 has a function of emitting visible light. Specifically, the light-emitting element 190 is an electroluminescent light-emitting element that emits light 121 toward the substrate 152 when voltage is applied between the pixel electrode 191 and the common electrode 115.

It is preferable that the light-emitting layer 193 be formed not to overlap with a light-receiving region of the light-receiving element 110. Accordingly, it is possible to inhibit the light-emitting layer 193 from absorbing the light 122, so that the amount of light with which the light-receiving element 110 is irradiated can be increased.

The pixel electrode 111 is electrically connected to a source or a drain of the transistor 131 through an opening provided in the insulating layer 214. The end portion of the pixel electrode 111 is covered with the partition 216.

The pixel electrode 191 is electrically connected to a source or a drain of the transistor 132 through an opening provided in the insulating layer 214. The end portion of the pixel electrode 191 is covered with the partition 216. The transistor 132 has a function of controlling driving of the light-emitting element 190.

The transistor 131 and the transistor 132 are on and in contact with the same layer (the substrate 151 in FIG. 9A).

At least part of a circuit electrically connected to the light-receiving element 110 is preferably formed using the same material in the same steps as a circuit electrically connected to the light-emitting element 190. Thus, the thickness of the display panel can be reduced and the manufacturing process can be simplified compared to the case where the two circuits are separately formed.

The light-receiving element 110 and the light-emitting element 190 are preferably covered with a protective layer 195. In FIG. 9A, the protective layer 195 is provided on and in contact with the common electrode 115. Providing the protective layer 195 can inhibit entry of impurities such as water into the light-receiving element 110 and the light-emitting element 190, so that the reliability of the light-receiving element 110 and the light-emitting element 190 can be increased. The protective layer 195 and the substrate 152 are attached to each other with an adhesive layer 142.

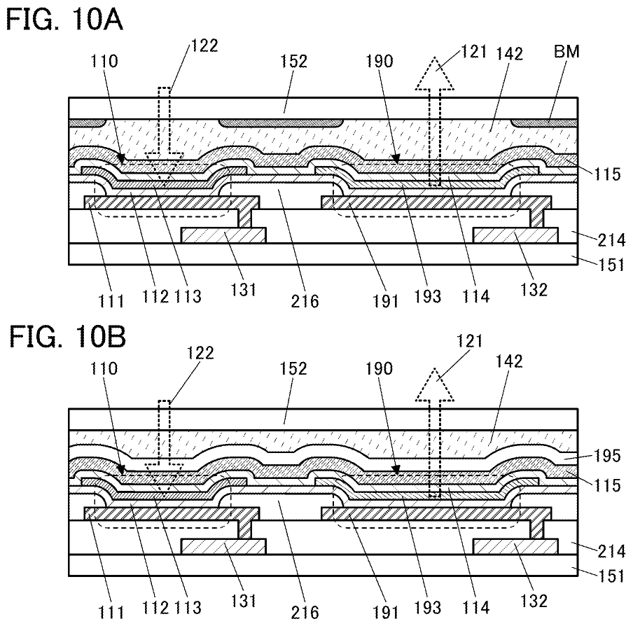

Note that as shown in FIG. 10A, the protective layer is not necessarily provided over the light-receiving element 110 and the light-emitting element 190. In FIG. 10A, the common electrode 115 and the substrate 152 are attached to each other with the adhesive layer 142.

As shown in FIG. 10B, the light-blocking layer BM is not necessarily provided. This structure can increase the light-receiving area of the light-receiving element 110, so that the sensitivity of the sensor can be further increased.

### Structure Example 2-2

FIG. 9B is a cross-sectional view of a display panel 100B. Note that in the following description of display panels, the description of components similar to those of the above display panel might be omitted.

The display panel 100B shown in FIG. 9B includes a lens 149 in addition to the components of the display panel 100A.

The lens 149 is provided at a position overlapping with the light-receiving element 110. In the display panel 100B, the lens 149 is provided in contact with the substrate 152. The lens 149 included in the display panel 100B is a convex lens having a convex surface on the substrate 151 side. Note that convex lens having a convex surface on the substrate 152 side may be provided in a region overlapping with the light-receiving element 110.

In the case where the light-blocking layer BM and the lens 149 are formed on the same plane of the substrate 152, their formation order is not limited. FIG. 9B shows an example in which the lens 149 is formed first; alternatively, the light-blocking layer BM may be formed first. In FIG. 9B, an end portion of the lens 149 is covered with the light-blocking layer BM.

In the display panel 100B, the light 122 is incident on the light-receiving element 110 through the lens 149. With the lens 149, the amount of the light 122 incident on the light-receiving element 110 can be increased compared to the case where the lens 149 is not provided. This can increase the sensitivity of the light-receiving element 110.

As a method for forming the lens used in the display panel of this embodiment, a lens such as a microlens may be formed directly over the substrate or the light-receiving element, or a lens array formed separately, such as a microlens array, may be attached to the substrate.

### Structure Example 2-3

FIG. 9C is a schematic cross-sectional view of a display panel 100C. The display panel 100C differs from the display panel 100A in that the substrate 151, the substrate 152, and the partition 216 are not included and a substrate 153, a substrate 154, an adhesive layer 155, an insulating layer 212, and a partition 217 are included.

The substrate 153 and the insulating layer 212 are attached to each other with the adhesive layer 155. The substrate 154 and the protective layer 195 are attached to each other with the adhesive layer 142.

The display panel 100C is formed in such a manner that the insulating layer 212, the transistor 131, the transistor 132, the light-receiving element 110, the light-emitting element 190, and the like that are formed over a formation substrate are transferred onto the substrate 153. The substrate 153 and the substrate 154 are preferably flexible. Accordingly, the display panel 100C can be highly flexible. For example, a resin is preferably used for each of the substrate 153 and the substrate 154.

For each of the substrate 153 and the substrate 154, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for one or both of the substrate 153 and the substrate 154.

For the substrate included in the display panel of this embodiment, a film having high optical isotropy may be used. Examples of the film having high optical isotropy include a triacetyl cellulose (TAC, also referred to as cellulose triacetate) film, a cycloolefin polymer (COP) film, a cycloolefin copolymer (COC) film, and an acrylic film.

The partition 217 preferably absorbs light emitted from the light-emitting element. As the partition 217, a black matrix can be formed using a resin material containing a pigment or dye, for example. The partition 217 can be formed using a colored insulating material such as a brown resist material.

In some cases, light 123c emitted from the light-emitting element 190 is reflected by the substrate 154 and the partition 217 and reflected light 123d is incident on the light-receiving element 110. In other cases, the light 123c passes through the partition 217 and is reflected by a transistor, a wiring, or the like, and thus the reflected light 123d is incident on the light-receiving element 110. When the partition 217 absorbs the light 123c, the reflected light 123d can be inhibited from being incident on the light-receiving element 110. Hence, noise can be reduced, and the sensitivity of the sensor using the light-receiving element 110 can be increased.

The partition 217 preferably absorbs at least light having a wavelength that is sensed by the light-receiving element 110. For example, in the case where the light-receiving element 110 senses red light emitted from the light-emitting element 190, the partition 217 preferably absorbs at least red light. For example, when the partition 217 includes a blue color filter, the partition 217 can absorb the red light 123c and thus the reflected light 123d can be inhibited from being incident on the light-receiving element 110.

### Structure Example 2-4

Although the light-emitting element and the light-receiving element include two common layers in the above example, one embodiment of the present invention is not limited thereto. Examples in which common layers have different structures are described below.

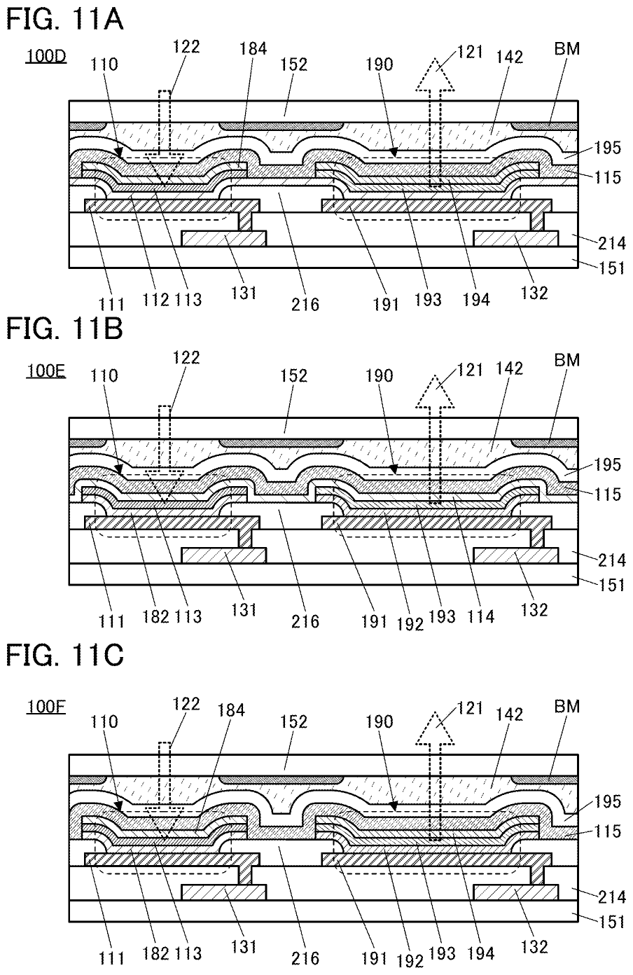

FIG. 11A is a schematic cross-sectional view of the display panel 100D. The display panel 100D differs from the display panel 100A in that the common layer 114 is not included and a buffer layer 184 and a buffer layer 194 are included. The buffer layer 184 and the buffer layer 194 may each have a single-layer structure or a stacked-layer structure.

In the display panel 100D, the light-receiving element 110 includes the pixel electrode 111, the common layer 112, the active layer 113, the buffer layer 184, and the common electrode 115. In the display panel 100D, the light-emitting element 190 includes the pixel electrode 191, the common layer 112, the light-emitting layer 193, the buffer layer 194, and the common electrode 115.

In the display panel 100D, an example is shown in which the buffer layer 184 between the common electrode 115 and the active layer 113 and the buffer layer 194 between the common electrode 115 and the light-emitting layer 193 are formed separately. As the buffer layer 184 and the buffer layer 194, one or both of an electron-injection layer and an electron-transport layer can be formed, for example.

FIG. 11B is a schematic cross-sectional view of the display panel 100E. The display panel 100E differs from the display panel 100A in that the common layer 112 is not included and a buffer layer 182 and a buffer layer 192 are included. The buffer layer 182 and the buffer layer 192 may each have a single-layer structure or a stacked-layer structure.

In the display panel 100E, the light-receiving element 110 includes the pixel electrode 111, the buffer layer 182, the active layer 113, the common layer 114, and the common electrode 115. In the display panel 100E, the light-emitting element 190 includes the pixel electrode 191, the buffer layer 192, the light-emitting layer 193, the common layer 114, and the common electrode 115.

In the display panel 100E, an example is shown in which the buffer layer 182 between the pixel electrode 111 and the active layer 113 and the buffer layer 192 between the pixel electrode 191 and the light-emitting layer 193 are formed separately. As the buffer layer 182 and the buffer layer 192, one or both of a hole-injection layer and a hole-transport layer can be formed, for example.

FIG. 11C is a schematic cross-sectional view of the display panel 100F. The display panel 100F differs from the display panel 100A in that the common layers 112 and 114 are not included and the buffer layers 182, 184, 192, and 194 are included.

In the display panel 100F, the light-receiving element 110 includes the pixel electrode 111, the buffer layer 182, the active layer 113, the buffer layer 184, and the common electrode 115. In the display panel 100F, the light-emitting element 190 includes the pixel electrode 191, the buffer layer 192, the light-emitting layer 193, the buffer layer 194, and the common electrode 115.

Other layers as well as the active layer 113 and the light-emitting layer 193 can be formed separately when the light-receiving element 110 and the light-emitting element 190 are manufactured.

In the example of the display panel 100F, in each of the light-receiving element 110 and the light-emitting element 190, a common layer is not provided between the pair of electrodes (the pixel electrode 111 or 191 and the common electrode 115). The light-receiving element 110 and the light-emitting element 190 included in the display panel 100F can be manufactured in the following manner: the pixel electrode 111 and the pixel electrode 191 are formed over the insulating layer 214 using the same material in the same step; the buffer layer 182, the active layer 113, and the buffer layer 184 are formed over the pixel electrode 111; the buffer layer 192, the light-emitting layer 193, and the buffer layer 194 are formed over the pixel electrode 191; and then, the common electrode 115 is formed to cover the buffer layer 184, the buffer layer 194, and the like.

Note that the manufacturing order of the stacked-layer structure of the buffer layer 182, the active layer 113, and the buffer layer 184 and the stacked-layer structure of the buffer layer 192, the light-emitting layer 193, and the buffer layer 194 is not particularly limited. For example, after the buffer layer 182, the active layer 113, and the buffer layer 184 are deposited, the buffer layer 192, the light-emitting layer 193, and the buffer layer 194 may be deposited. In contrast, the buffer layer 192, the light-emitting layer 193, and the buffer layer 194 may be deposited before the buffer layer 182, the active layer 113, and the buffer layer 184 are deposited. Alternatively, the buffer layer 182, the buffer layer 192, the active layer 113, and the light-emitting layer 193 may be deposited in that order, for example.

### Structure Example 3 of Display Panel

More specific structure examples of the display panel are described below.

### Structure Example 3-1

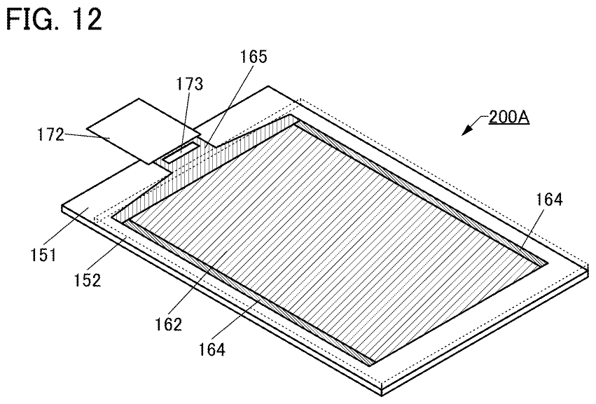

FIG. 12 is a perspective view of a display panel 200A.

In the display panel 200A, the substrate 151 and the substrate 152 are attached to each other. In FIG. 12, the substrate 152 is indicated by a dashed line.

The display panel 200A includes a display portion 162, circuits 164, a wiring 165, and the like. FIG. 12 shows an example in which an integrated circuit (IC) 173 and an FPC 172 are mounted on the display panel 200A. Thus, the structure shown in FIG. 12 can be regarded as a display module including the display panel 200A, the IC, and the FPC.

As the circuits 164, scan line driver circuits can be used.

The wiring 165 has a function of supplying a signal and power to the display portion 162 and the circuits 164. The signal and power are input to the wiring 165 from the outside through the FPC 172 or from the IC 173.

FIG. 12 shows an example in which the IC 173 is provided over the substrate 151 by a chip on glass (COG) method, a chip on film (COF) method, or the like. An IC including a scan line driver circuit, a signal line driver circuit, or the like can be used as the IC 173, for example. Note that the display panel 200A and the display module are not necessarily provided with an IC. The IC may be mounted on the FPC by a COF method or the like.

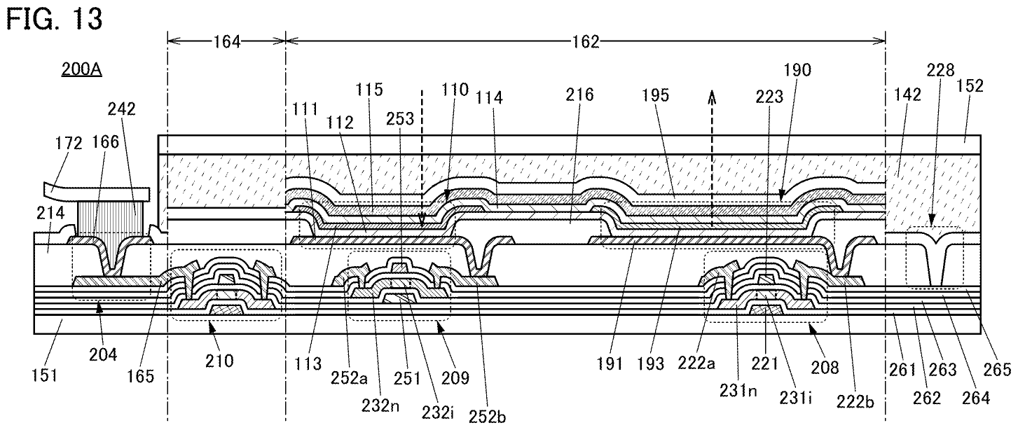

FIG. 13 shows an example of cross sections of part of a region including the FPC 172, part of a region including the circuit 164, part of a region including the display portion 162, and part of a region including an end portion of the display panel 200A shown in FIG. 12.

The display panel 200A includes a transistor 208, a transistor 209, a transistor 210, the light-emitting element 190, the light-receiving element 110, and the like between the substrate 151 and the substrate 152.

The transistor 208 and the transistor 210 each contain low-temperature polysilicon in a semiconductor layer where a channel is formed. The transistor 209 contains a metal oxide in a semiconductor layer where a channel is formed.

The transistor 208, the transistor 209, and the transistor 210 are formed over the substrate 151. These transistors can be at least partly fabricated using the same material in the same step.

An insulating layer 261, an insulating layer 262, an insulating layer 263, an insulating layer 264, and an insulating layer 265 are provided in this order over the substrate 151. Part of the insulating layer 261 functions as a second gate insulating layer of the transistor 208. Part of the insulating layer 262 functions as a first gate insulating layer of the transistor 208. The insulating layer 263 is provided to cover the transistor 208, and part of the insulating layer 263 functions as a second gate insulating layer of the transistor 209. The insulating layer 264 is provided to cover the transistor 208, and part of the insulating layer 264 functions as a first gate insulating layer of the transistor 209. The insulating layer 265 is provided to cover the transistor 208 and the transistor 209. The insulating layer 214 is provided over the insulating layer 265. The insulating layer 214 functions as a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This is because such an insulating layer can function as a barrier layer. Such a structure can effectively inhibit diffusion of impurities into the transistors from the outside and increase the reliability of a display device.

An inorganic insulating film is preferably used as each of the insulating layers 261, 262, 263, 264, and 265. As the inorganic insulating film, an inorganic insulating film such as a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

Here, an organic insulating film often has a lower barrier property than an inorganic insulating film. Therefore, the organic insulating film preferably has an opening in the vicinity of an end portion of the display panel 200A. This can inhibit entry of impurities from the end portion of the display panel 200A through the organic insulating film. Alternatively, the organic insulating film may be formed such that its end portion is positioned on the inner side compared to the end portion of the display panel 200A, to prevent the organic insulating film from being exposed at the end portion of the display panel 200A.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

Each of the transistors 208 and 210 includes a conductive layer 221 functioning as a second gate, the insulating layer 261 functioning as the second gate insulating layer, a semiconductor layer including a channel formation region 231i and a pair of low-resistance regions 231n, a conductive layer 222a connected to one of the low-resistance regions 231n, a conductive layer 222b connected to the other of the low-resistance regions 231n, the insulating layer 262 functioning as the first gate insulating layer, a conductive layer 223 functioning as a first gate, and the insulating layer 263 covering the conductive layer 223. Part of the insulating layer 261 is positioned between the conductive layer 221 and the channel formation region 231i. Part of the insulating layer 262 is positioned between the conductive layer 223 and the channel formation region 231i.

The conductive layer 222a and the conductive layer 222b are connected to the low-resistance regions 231n through openings provided in the insulating layer 262, the insulating layer 263, the insulating layer 264, and the insulating layer 265. One of the conductive layers 222a and 222b functions as a source electrode, and the other functions as a drain electrode.

The transistor 209 includes a conductive layer 251 functioning as a second gate, the insulating layer 263 functioning as the second gate insulating layer, a semiconductor layer including a channel formation region 232i and a pair of low-resistance regions 232n, a conductive layer 252a connected to one of the low-resistance regions 232n, a conductive layer 252b connected to the other of the low-resistance regions 232n, the insulating layer 264 functioning as the first gate insulating layer, a conductive layer 253 functioning as a first gate, and the insulating layer 265 covering the conductive layer 253. Part of the insulating layer 263 is positioned between the conductive layer 251 and the channel formation region 232i. Part of the insulating layer 264 is positioned between the conductive layer 253 and the channel formation region 232i.

The conductive layer 252a and the conductive layer 252b are connected to the low-resistance regions 232n through openings provided in the insulating layer 264 and the insulating layer 265. One of the conductive layers 252a and 252b functions as a source electrode, and the other functions as a drain electrode.

There is no particular limitation on the structure of the transistors included in the display panel of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The transistors 208, 209, and 210 each have a structure in which the semiconductor layer where a channel is formed is positioned between two gates. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity because degradation of transistor characteristics can be inhibited.

In each of the transistors 208, 209, and 210, a semiconductor layer containing silicon is preferably used.

Alternatively, it is preferable that a semiconductor layer of the transistor 209 contain a metal oxide (also referred to as an oxide semiconductor). A semiconductor layer of each of the transistors 208 and 210 preferably contains silicon. Examples of silicon include amorphous silicon and crystalline silicon (e.g., low-temperature polysilicon or single crystal silicon).

The semiconductor layer containing a metal oxide preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium, gallium, and zinc (also referred to as IGZO) be used for the semiconductor layer containing a metal oxide.

In the case where the semiconductor layer is an In-M-Zn oxide, the atomic ratio of In to M in a sputtering target used for depositing the In-M-Zn oxide is preferably 1 or more. The atomic ratio of metal elements in such a sputtering target is, for example, In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, or In:M:Zn=5:2:5.

A target containing a polycrystalline oxide is preferably used as the sputtering target, which facilitates formation of a semiconductor layer having crystallinity. Note that the atomic ratio in the semiconductor layer to be deposited varies within the range of ±40% from any of the atomic ratios of the metal elements contained in the sputtering target. For example, in the case where the composition of a sputtering target used for the semiconductor layer is In:Ga:Zn=4:2:4.1 [atomic ratio], the composition of the deposited semiconductor layer is in the neighborhood of In:Ga:Zn=4:2:3 [atomic ratio] in some cases.

Note that when the atomic ratio is described as In:Ga:Zn=4:2:3 or as being in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or as being in the neighborhood thereof, the case is included where the atomic proportion of Ga is greater than 0.1 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or as being in the neighborhood thereof, the case is included where the atomic proportion of Ga is greater than 0.1 and less than or equal to 2 and the atomic proportion of Zn is greater than 0.1 and less than or equal to 2 with the atomic proportion of In being 1.

The transistor included in the circuit 164 and the transistor included in the display portion 162 may have the same structure or different structures. One structure or two or more kinds of structures may be employed for a plurality of transistors included in the circuit 164. Similarly, one structure or two or more kinds of structures may be employed for a plurality of transistors included in the display portion 162.

Here, the transistor having the same structure as the transistor 208 is illustrated as the transistor 210 included in the circuit 164. The circuit 164 may be formed using transistors each having the same structure as the transistor 210. Alternatively, a transistor having the same structure as the transistor 208 and a transistor having the same structure as the transistor 209 may be used in combination in the circuit 164.

Here, the conductive layer 251 and the conductive layer 223 are positioned on the same plane and formed by processing the same conductive film. The conductive layer 222a, the conductive layer 222b, the conductive layer 252a, the conductive layer 252b, and the like are positioned on the same plane and are formed by processing the same conductive film.

The light-emitting element 190 has a stacked-layer structure in which the pixel electrode 191, the common layer 112, the light-emitting layer 193, the common layer 114, and the common electrode 115 are stacked in this order from the insulating layer 214 side. The pixel electrode 191 is connected to the conductive layer 222b included in the transistor 208 through an opening provided in the insulating layer 214. The transistor 208 has a function of controlling a current flowing through the light-emitting element 190. An end portion of the pixel electrode 191 is covered with the partition 216. The pixel electrode 191 contains a material that reflects visible light, and the common electrode 115 contains a material that transmits visible light.

The light-receiving element 110 has a stacked-layer structure in which the pixel electrode 111, the common layer 112, the active layer 113, the common layer 114, and the common electrode 115 are stacked in that order from the insulating layer 214 side. The pixel electrode 111 is electrically connected to the conductive layer 252b included in the transistor 209 through an opening provided in the insulating layer 214. The end portion of the pixel electrode 111 is covered with the partition 216. The pixel electrode 111 contains a material that reflects visible light, and the common electrode 115 contains a material that transmits visible light.

Light from the light-emitting element 190 is emitted toward the substrate 152. Light is incident on the light-receiving element 110 through the substrate 152 and the adhesive layer 142. For the substrate 152, a material having a high visible-light-transmitting property is preferably used.

The pixel electrode 111 and the pixel electrode 191 can be formed using the same material in the same step. The common layer 112, the common layer 114, and the common electrode 115 are used in both the light-receiving element 110 and the light-emitting element 190. The light-receiving element 110 and the light-emitting element 190 can have common components except the active layer 113 and the light-emitting layer 193. Thus, the light-receiving element 110 can be incorporated in the display panel 200A without a significant increase in the number of manufacturing steps.

The protective layer 195 is provided to cover the light-receiving element 110 and the light-emitting element 190. The protective layer 195 can inhibit diffusion of impurities such as water into the light-receiving element 110 and the light-emitting element 190, thereby increasing the reliability of the light-receiving element 110 and the light-emitting element 190.

In a region 228 shown in FIG. 13, an opening is formed in the insulating layer 214. This can inhibit entry of impurities into the display portion 162 from the outside through the insulating layer 214 even when an organic insulating film is used as the insulating layer 214. Consequently, the reliability of the display panel 200A can be increased.

In the region 228 in the vicinity of an end portion of the display panel 200A, the insulating layer 265 and the protective layer 195 are preferably in contact with each other through an opening in the insulating layer 214. In particular, the inorganic insulating film included in the insulating layer 265 and an inorganic insulating film included in the protective layer 195 are preferably in contact with each other. Thus, diffusion of impurities from the outside into the display portion 162 through an organic insulating film can be inhibited. Accordingly, the reliability of the display panel 200A can be increased.

The protective layer 195 preferably has a stacked-layer structure of an organic insulating film and an inorganic insulating film. For example, the protective layer 195 preferably has a three-layer structure of an inorganic insulating layer, an organic insulating layer, and an inorganic insulating layer over the common electrode 115. In that case, end portions of the inorganic insulating layers preferably extend beyond an end portion of the organic insulating layer.

In the display panel 200A, the protective layer 195 and the substrate 152 are attached to each other with the adhesive layer 142. The adhesive layer 142 is provided to overlap with the light-receiving element 110 and the light-emitting element 190. That is, the display panel 200A has a solid sealing structure.

A connection portion 204 is provided in a region of the substrate 151 where the substrate 152 does not overlap. In the connection portion 204, the wiring 165 is electrically connected to the FPC 172 through a conductive layer 166 and a connection layer 242. On the top surface of the connection portion 204, the conductive layer 166 obtained by processing the same conductive film as the pixel electrode 191 is exposed. Thus, the connection portion 204 and the FPC 172 can be electrically connected to each other through the connection layer 242.

A variety of optical members can be arranged on the outer surface of the substrate 152. Examples of the optical members include a polarizing plate, a retardation plate, a light diffusion layer (e.g., a diffusion film), an anti-reflective layer, and a light-condensing film. Furthermore, an antistatic film preventing the attachment of dust, a water repellent film suppressing the attachment of stain, a hard coat film suppressing generation of a scratch caused by the use, an impact-absorbing layer, or the like may be arranged on the outer surface of the substrate 152. A touch sensor panel may be provided on the outer surface of the substrate 152. A touch sensor of any of various types such as a resistive type, a capacitive type, an infrared ray type, an electromagnetic induction type, and a surface acoustic wave type can be used as the touch sensor included in the touch sensor panel. As the touch sensor, a capacitive touch sensor is particularly preferable.

For each of the substrates 151 and 152, glass, quartz, ceramic, sapphire, a resin, or the like can be used. When each of the substrates 151 and 152 is formed using a flexible material, the flexibility of the display panel can be increased.

As the adhesive layer, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferred. A two-component-mixture-type resin may be used. An adhesive sheet or the like may be used.

As the connection layer 242, an anisotropic conductive film (ACF), an anisotropic conductive paste (ACP), or the like can be used.

The light-emitting element 190 may be a top emission, bottom emission, or dual emission light-emitting element, or the like. A conductive film that transmits visible light is used as the electrode through which light is extracted. A conductive film that reflects visible light is preferably used as the electrode through which light is not extracted.

The light-emitting element 190 includes at least the light-emitting layer 193. In addition to the light-emitting layer 193, the light-emitting element 190 may further include a layer containing any of a substance with a high hole-injection property, a substance with a high hole-transport property, a hole-blocking material, a substance with a high electron-transport property, a substance with a high electron-injection property, an electron-blocking material, a substance with a bipolar property (a substance with a high electron- and hole-transport property), and the like. For example, the common layer 112 preferably includes one or both of a hole-injection layer and a hole-transport layer. For example, the common layer 114 preferably includes one or both of an electron-transport layer and an electron-injection layer.

Either a low-molecular compound or a high-molecular compound can be used for the common layer 112, the light-emitting layer 193, and the common layer 114, and an inorganic compound may also be contained. The layers included in the common layer 112, the light-emitting layer 193, and the common layer 114 can be formed by any of the following methods, for example: an evaporation method (including a vacuum evaporation method), a transfer method, a printing method, an inkjet method, and a coating method.

The light-emitting layer 193 may contain an inorganic compound such as quantum dots.

The active layer 113 of the light-receiving element 110 contains a semiconductor. Examples of the semiconductor include an inorganic semiconductor such as silicon and an organic semiconductor including an organic compound. This embodiment shows an example in which an organic semiconductor is used as the semiconductor contained in the active layer. The use of an organic semiconductor is preferable because the light-emitting layer 193 of the light-emitting element 190 and the active layer 113 of the light-receiving element 110 can be formed by the same method (e.g., a vacuum evaporation method) and thus the same manufacturing apparatus can be used.

Examples of an n-type semiconductor material contained in the active layer 113 include electron-accepting organic semiconductor materials such as fullerene (e.g., C₆₀ and C₇₀) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). When π-electron conjugation (resonance) spreads in a plane as in benzene, the electron-donating property (donor property) usually increases. Although π-electrons widely spread in fullerene having a spherical shape, its electron-accepting property is high. The high electron-accepting property efficiently causes rapid charge separation and is useful for light-receiving devices. Both C₆₀ and C₇₀ have a wide absorption band in the visible light region, and C₇₀ is especially preferable because of having a larger π-electron conjugation system and a wider absorption band in the long wavelength region than C₆₀.

Other examples of the n-type semiconductor material contained in the active layer 113 include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer 113 include electron-donating organic semiconductor materials such as copper(II) phthalocyanine (CuPc), tetraphenyldibenzoperiflanthene (DBP), zinc phthalocyanine (ZnPc), tin phthalocyanine (SnPc), and quinacridone.

Examples of a p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

For example, the active layer 113 is preferably formed by co-evaporation of an n-type semiconductor and a p-type semiconductor. Alternatively, the active layer 113 may be formed by stacking an n-type semiconductor and a p-type semiconductor.

As materials of a gate, a source, and a drain of a transistor, and conductive layers functioning as wirings and electrodes included in the display panel, any of metals such as aluminum, titanium, chromium, nickel, copper, yttrium, zirconium, molybdenum, silver, tantalum, tungsten, and niobium, or an alloy containing one or more of these metals can be used. A single-layer structure or a stacked-layer structure including a film containing any of these materials can be used.

As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, an alloy material containing any of these metal materials, or the like can be used. Alternatively, a nitride of the metal material (e.g., titanium nitride) or the like may be used. Note that in the case of using the metal material or the alloy material (or the nitride thereof), the thickness is preferably set small enough to transmit light. Alternatively, a stacked film of any of the above materials can be used for the conductive layers. For example, a stacked film of indium tin oxide and an alloy of silver and magnesium is preferably used because conductivity can be increased. These materials can also be used for conductive layers such as wirings and electrodes included in the display panel, conductive layers (e.g., a conductive layer functioning as a pixel electrode or a common electrode) included in a display element, and the like.

Examples of insulating materials that can be used for the insulating layers include a resin material such as acrylic, epoxy, or polyimide and an inorganic insulating material such as silicon oxide, silicon oxynitride, silicon nitride oxide, silicon nitride, or aluminum oxide.

### Structure Example 3-2

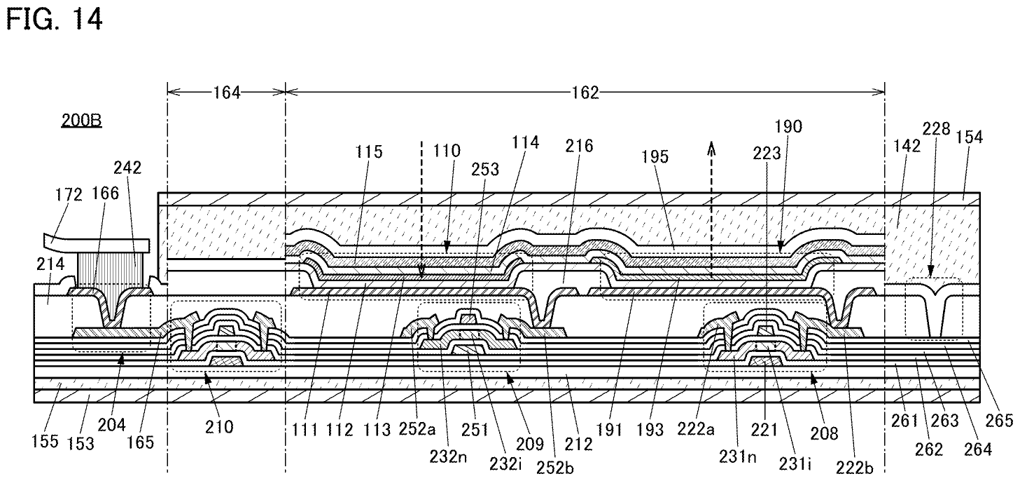

FIG. 14 is a cross-sectional view of a display panel 200B. The display panel 200B differs from the display panel 200A mainly in the substrate structure.

The display panel 200B includes neither the substrate 151 nor the substrate 152 and includes the substrate 153, the substrate 154, the adhesive layer 155, and the insulating layer 212.

The substrate 153 and the insulating layer 212 are attached to each other with the adhesive layer 155. The substrate 154 and the protective layer 195 are attached to each other with the adhesive layer 142.

The display panel 200B is formed in such a manner that the insulating layer 212, the transistor 208, the transistor 209, the light-receiving element 110, the light-emitting element 190, and the like that are formed over a formation substrate are transferred onto the substrate 153. The substrate 153 and the substrate 154 are preferably flexible. Accordingly, the display panel 200B can be highly flexible.

The inorganic insulating film that can be used as the insulating layer 261, the insulating layer 262, the insulating layer 263, the insulating layer 264, and the insulating layer 265 can be used as the insulating layer 212. Alternatively, a stacked film of an organic insulating film and an inorganic insulating film may be used as the insulating layer 212. In that case, a film on the transistor 208 side is preferably an inorganic insulating film.

The above is the description of the structure examples of the display panel.

### [Metal Oxide]

A metal oxide that can be used for the semiconductor layer is described below.

Note that in this specification and the like, a metal oxide containing nitrogen is also referred to as a metal oxide in some cases. In addition, a metal oxide containing nitrogen may be referred to as a metal oxynitride. For example, a metal oxide containing nitrogen, such as zinc oxynitride (ZnON), may be used for the semiconductor layer.

Note that the terms “c-axis aligned crystal (CAAC)” and “cloud-aligned composite (CAC)” might appear in this specification and the like. CAAC refers to an example of a crystal structure, and CAC refers to an example of a function or a material composition.

For example, a cloud-aligned composite oxide semiconductor (CAC-OS) can be used for the semiconductor layer.

A CAC-OS or a CAC-metal oxide has a conducting function in part of the material and has an insulating function in another part of the material; as a whole, the CAC-OS or the CAC-metal oxide has a function of a semiconductor. Note that in the case where the CAC-OS or the CAC-metal oxide is used in a semiconductor layer of a transistor, the conducting function is a function that allows electrons (or holes) serving as carriers to flow, and the insulating function is a function that does not allow electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

Furthermore, the CAC-OS or the CAC-metal oxide includes conductive regions and insulating regions. The conductive regions have the above conducting function, and the insulating regions have the above insulating function. Furthermore, in some cases, the conductive regions and the insulating regions in the material are separated at the nanoparticle level. Furthermore, in some cases, the conductive regions and the insulating regions are unevenly distributed in the material. Furthermore, the conductive regions are observed to be coupled in a cloud-like manner with their boundaries blurred, in some cases.

Furthermore, in the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

Furthermore, the CAC-OS or the CAC-metal oxide includes components having different bandgaps. For example, the CAC-OS or the CAC-metal oxide includes a component having a wide gap due to the insulating region and a component having a narrow gap due to the conductive region. In the case of the structure, when carriers flow, carriers mainly flow through the component having a narrow gap. Furthermore, the component having a narrow gap complements the component having a wide gap, and carriers also flow through the component having a wide gap in conjunction with the component having a narrow gap. Therefore, in the case where the CAC-OS or the CAC-metal oxide is used for the channel formation region of the transistor, high current drive capability in an on state of the transistor, that is, high on-state current and high field-effect mobility can be obtained.

In other words, the CAC-OS or the CAC-metal oxide can also be referred to as a matrix composite or a metal matrix composite.

Oxide semiconductors (metal oxides) are classified into a single crystal oxide semiconductor and a non-single crystal oxide semiconductor. Examples of a non-single crystal oxide semiconductor include a CAAC-OS (c-axis aligned crystalline oxide semiconductor), a polycrystalline oxide semiconductor, a nanocrystalline oxide semiconductor (nc-OS), an amorphous-like oxide semiconductor (a-like OS), and an amorphous oxide semiconductor.

The CAAC-OS has c-axis alignment, a plurality of nanocrystals are connected in the a-b plane direction, and its crystal structure has distortion. Note that the distortion refers to a portion where the direction of lattice arrangement changes between a region with regular lattice arrangement and another region with regular lattice arrangement in a region where the plurality of nanocrystals are connected.

The nanocrystal is basically a hexagon but is not always a regular hexagon and is a non-regular hexagon in some cases. Furthermore, pentagonal lattice arrangement, heptagonal lattice arrangement, and the like are included in the distortion in some cases. Note that it is difficult to observe a clear crystal grain boundary (also referred to as grain boundary) even in the vicinity of distortion in the CAAC-OS. That is, formation of a crystal grain boundary is inhibited by the distortion of lattice arrangement. This is because the CAAC-OS can tolerate distortion owing to the low density of oxygen atom arrangement in the a-b plane direction, a change in interatomic bond distance by replacement of a metal element, and the like.

Furthermore, the CAAC-OS tends to have a layered crystal structure (also referred to as a layered structure) in which a layer containing indium and oxygen (hereinafter referred to as an In layer) and a layer containing the element M, zinc, and oxygen (hereinafter referred to as an (M, Zn) layer) are stacked. Note that indium and the element M can be replaced with each other, and when the element M in the (M, Zn) layer is replaced with indium, the layer can also be referred to as an (In, M, Zn) layer. Furthermore, when indium in the In layer is replaced with the element M, the layer can also be referred to as an (In, M) layer.

The CAAC-OS is a metal oxide with high crystallinity. Meanwhile, in the CAAC-OS, it can be said that a reduction in electron mobility due to the crystal grain boundary is less likely to occur because it is difficult to observe a clear crystal grain boundary. Furthermore, the mixing of impurities, formation of defects, or the like might decrease the crystallinity of the metal oxide; thus, it can also be said that the CAAC-OS is a metal oxide having small amounts of impurities and defects (e.g., oxygen vacancies (V_{O})). Thus, a metal oxide including a CAAC-OS is physically stable. Therefore, the metal oxide including a CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor depending on the analysis method.

Note that indium-gallium-zinc oxide (hereinafter referred to as IGZO) that is a kind of metal oxide containing indium, gallium, and zinc has a stable structure in some cases when formed of the nanocrystals. In particular, IGZO crystals tend not to grow in the air and thus, a stable structure is obtained in some cases when IGZO is formed of smaller crystals (e.g., the nanocrystals) rather than larger crystals (here, crystals with a size of several millimeters or several centimeters).

The a-like OS is a metal oxide that has a structure between those of the nc-OS and the amorphous oxide semiconductor. The a-like OS includes a void or a low-density region. That is, the a-like OS has lower crystallinity than the nc-OS and the CAAC-OS.

An oxide semiconductor (a metal oxide) has various structures with different properties. Two or more kinds of the amorphous oxide semiconductor, the polycrystalline oxide semiconductor, the a-like OS, the nc-OS, and the CAAC-OS may be included in an oxide semiconductor of one embodiment of the present invention.

A metal oxide film that functions as a semiconductor layer can be deposited using either or both of an inert gas and an oxygen gas. Note that there is no particular limitation on the flow rate ratio of oxygen (the partial pressure of oxygen) at the time of deposition of the metal oxide film. However, to obtain a transistor having high field-effect mobility, the flow rate ratio of oxygen (the partial pressure of oxygen) at the time of deposition of the metal oxide film is preferably higher than or equal to 0% and lower than or equal to 30%, further preferably higher than or equal to 5% and lower than or equal to 30%, still further preferably higher than or equal to 7% and lower than or equal to 15%.

The energy gap of the metal oxide is preferably greater than or equal to 2 eV, further preferably greater than or equal to 2.5 eV, still further preferably greater than or equal to 3 eV. With the use of a metal oxide having such a wide energy gap, the off-state current of the transistor can be reduced.

The substrate temperature during the deposition of the metal oxide film is preferably lower than or equal to 350° C., further preferably higher than or equal to room temperature and lower than or equal to 200° C., still further preferably higher than or equal to room temperature and lower than or equal to 130° C. The substrate temperature during the deposition of the metal oxide film is preferably room temperature because productivity can be increased.

The metal oxide film can be formed by a sputtering method. Alternatively, a PLD method, a PECVD method, a thermal CVD method, an ALD method, a vacuum evaporation method, or the like may be used.

The above is the description of the metal oxide.

At least part of this embodiment can be implemented in combination with any of the other embodiments described in this specification as appropriate.

### Embodiment 3

In this embodiment, a display system using any of the display devices of one embodiment of the present invention is described.

The display system of one embodiment of the present invention includes a display device with a display portion (also referred to as a screen) displaying an image and a light-emitting apparatus emitting laser light. The light-emitting apparatus can be used as a laser pointer.

The light-emitting apparatus includes a light source emitting visible laser light and a light source emitting nonvisible light. Nonvisible light does not include visible light but may include ultraviolet light, infrared light, or an electromagnetic wave (electric wave) having a longer wavelength than infrared light. It is preferable to use, as nonvisible light, light having a longer wavelength than visible light, and it is particularly preferable to use infrared light.

In the display portion of the display device, a plurality of pixels for displaying an image are arranged in a matrix. Each of the pixels includes at least one display element and a light-receiving element. The light-receiving element receives the above-described visible laser light to convert the laser light into an electric signal (also referred to as a first electric signal). The light-receiving elements are arranged in a matrix in the display portion, whereby the display device can obtain data of a position which is irradiated with the visible laser light.

The display device includes a light-receiving portion that receives the above-described nonvisible light in a position not provided with the display portion.

In the display device, when the light-receiving portion receives nonvisible light, various types of processing can be executed on the basis of the data of the position which is irradiated with visible laser light. For example, processing for a character input function, a drawing function, or the like can be executed, as well as processing such as selection, execution, transfer, or the like of an object displayed on the screen. Furthermore, processing for a gesture input function can also be executed in accordance with the locus of positions irradiated with visible laser light. Note that the types of processing given here are merely examples of the processing the display system can execute, and various types of processing may be executed in accordance with application software incorporated in the display system.

As described above, in the display system of one embodiment of the present invention, the light-emitting apparatus functioning as a laser pointer can also function as an input device such as a pointing device. This removes the necessity for an input device such as a mouse or a touch pad that has been conventionally needed, which leads to an increase in convenience.

Furthermore, when data is included in the nonvisible light emitted from the light-emitting apparatus, the display system can be much more convenient. For example, when nonvisible light includes identification data of a light-emitting apparatus, a plurality of users can operate the display system at the same time. Furthermore, nonvisible light can include data depending on the structure or operation method of a switch for controlling the nonvisible light. For example, the time, timing, or the like of emission of nonvisible light is used as data, whereby a function equivalent to clicking, double-clicking, or long pressing of a mouse can be performed. In addition, analog input can be achieved by providing a plurality of switches for controlling nonvisible light, using input means such as a touch pad or a dial as the switches, or the like. In the case where data is included in nonvisible light, the data is preferably overlapped with the nonvisible light by a modulation method such as pulse position modulation (PPM) or the like.

Here, the display element and the light-receiving element provided in the display portion of the display device are preferably formed over the same substrate. In that case, an organic electroluminescent element (organic EL element) containing an organic compound in a light-emitting layer is preferably used as the display element and an organic photodiode containing an organic compound in an active layer is preferably used as the light-receiving element. In addition, some of the manufacturing steps of the display element also serve as some of the manufacturing steps of the light-receiving element, whereby manufacturing cost can be reduced and the manufacturing yield can be increased.

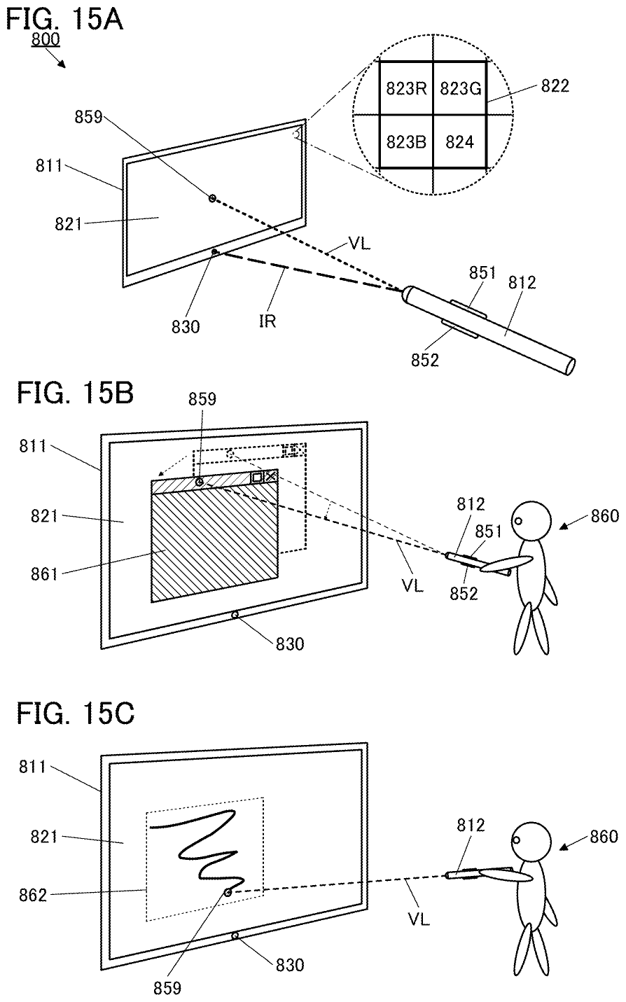

FIG. 15A illustrates a schematic view of a display system 800. The display system 800 includes a display device 811 and a light-emitting apparatus 812.

The light-emitting apparatus 812 includes a switch 851 and a switch 852 which are provided for a housing. The light-emitting apparatus 812 can emit visible light VL and infrared light IR from a tip of the housing. The visible light VL and the infrared light IR are emitted by the operation of the switch 851 and by the operation of the switch 852, respectively. Here, an example is shown in which a physical switch is used as each of the switch 851 and the switch 852.

The visible light VL is light with high directivity, and the infrared light IR is light with directivity lower than that of the visible light VL.

Laser light is preferably used as the visible light VL. For example, it is preferable to use red laser light (e.g., light with a peak wavelength of greater than or equal to 620 nm and less than or equal to 700 nm) or green laser light (e.g., light with a peak wavelength of greater than or equal to 500 nm and less than or equal to 550 nm, typically around 532 nm). Furthermore, the laser light is not limited to the above and can be light with a peak wavelength in a visible-light region (e.g., 350 nm to 750 nm). For example, laser light with a variety of colors such as blue, yellow, orange, navy, or purple can also be used.

Light with a peak wavelength in a near-infrared region (greater than or equal to 750 nm and less than or equal to 2500 nm) is preferably used as the infrared light IR. In addition, the directional characteristic (e.g., the viewing angle or full angle at half maximum) of the emission intensity is preferably wider than that of the visible light VL. For example, it is preferable to use light with a full angle at half maximum of greater than or equal to 30°, preferably greater than or equal to 40°, further preferably greater than or equal to 50° and less than or equal to 180°. Thus, in the state where a display portion 821 to be described later in the display device 811 is irradiated with the visible light VL, a light-receiving portion 830 provided outside the display portion 821 can be irradiated with the infrared light IR.

The display device 811 includes the display portion 821 and the light-receiving portion 830.

The display portion 821 is a region of the display device 811 where an image is displayed, and can also be referred to as a screen. The display portion 821 has a function of receiving the visible light VL emitted from the light-emitting apparatus 812 and obtaining data of a position of an irradiated region 859 that is irradiated with the visible light VL.

A plurality of display elements 823 and a plurality of light-receiving elements 824 are arranged in a matrix in the display portion 821. An enlarged view of part of the display portion 821 is shown in FIG. 15A. An example is shown in which one pixel 822 includes a display element 823R emitting red light, a display element 823B emitting blue light, a display element 823G emitting green light (hereinafter, the display elements are collectively referred to as the display element 823 in some cases), and the light-receiving element 824 that receives visible light to convert the visible light into an electric signal.

The light-receiving portion 830 has a function of receiving the infrared light IR emitted from the light-emitting apparatus 812 and converting the infrared light IR into an electric signal. The light-receiving portion 830 may be provided with a plurality of light-receiving elements that receive the infrared light IR or one light-receiving element. Although an example where the light-receiving portion 830 is provided outside the display portion 821 is illustrated, the light-receiving portion 830 may be positioned on an inner side than the outline of the display portion 821. Alternatively, an element that can receive both the visible light VL and the infrared light IR may be used as the light-receiving element 824 and the display portion 821 may also serve as the light-receiving portion 830.

FIG. 15B schematically illustrates the display device 811 and a user 860 operating the screen using the light-emitting apparatus 812.

The user 860 can perform emission of the visible light VL when operating the switch 851 of the light-emitting apparatus 812. In addition, by operating the switch 852 of the light-emitting apparatus 812, the display system 800 can execute various types of processing with the infrared light IR (not illustrated).

An object 861 is display on the display portion 821.

FIG. 15B illustrates the state where the user 860 is moving the object 861 displayed on the display portion 821 using the light-emitting apparatus 812.

When the visible light VL is emitted such that the irradiated region 859 is positioned in part of the object 861 (the upper portion of the object 861 in FIG. 15B) and the irradiated region 859 is moved, the object 861 can be moved along the locus of the irradiated region 859.

This operation corresponds to the drag operation in the case of using a mouse. For example, the user 860 can drag the object 861 by moving the irradiated region 859 with the switch 852 pressed, and can determine the position of the object 861 by releasing the switch 852.

FIG. 15C illustrates the state where the display system 800 is executing a drawing function. The user 860 can draw a figure (an object 862) along the locus of the irradiated region 859 on the display portion 821 by operating the light-emitting apparatus 812.

Although not illustrated here, an icon for changing the thickness, the kind, the color, or the like of a drawing line may be displayed on the display portion 821, for example. A function of drawing various figures such as a rectangle, a polygon, a circle, an ellipse, and a half circle as well as a line may be given.

According to one embodiment of the present invention, a display system that can execute processing on the basis of data of a position irradiated with visible laser light in a display portion and data included in nonvisible light received by a light-receiving portion and reflect the processing result in display can be provided. One embodiment of the present invention is a display device which can achieve the display system, and another embodiment of the present invention is a light-emitting apparatus which can achieve the display system. The display device and the light-emitting apparatus that can constitute the display system can be manufactured and sold independently of each other.

According to one embodiment of the present invention, a display system with a high convenience, a display system capable of easy operation of a screen using a laser pointer, a display system capable of operation of a screen by a plurality of users, or the like can be achieved. For example, the display system can be favorably used in a conference or a presentation or for digital signage or a multiplayer game.

At least part of this embodiment can be implemented in combination with any of the other embodiments described in this specification as appropriate.

### Embodiment 4

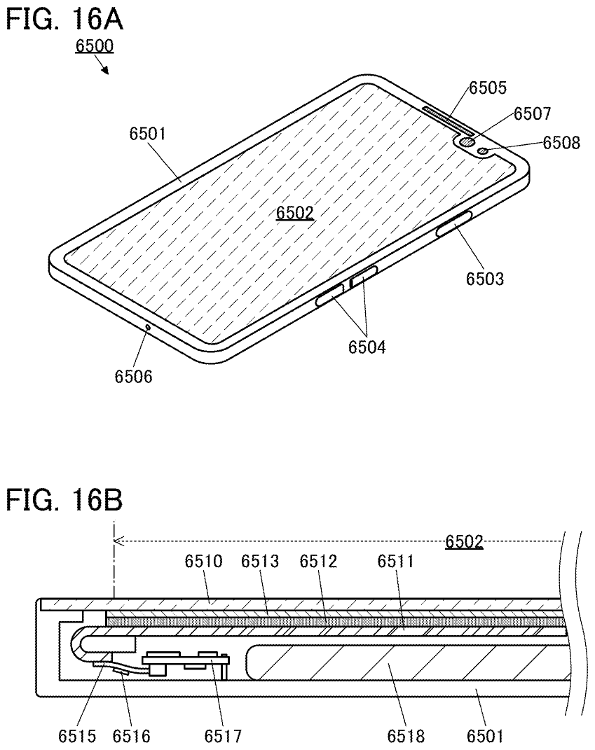

In this embodiment, electronic devices that can include the display device of one embodiment of the present invention will be described with reference to FIGS. 16A and 16B, FIGS. 17A to 17D, and FIGS. 18A to 18F.

An electronic device in this embodiment includes the display device of one embodiment of the present invention. The display device has a function of sensing light, and thus can perform biological authentication and sense a touch or an approach (non-contact) with the display portion. Unauthorized use of the electronic device of one embodiment of the present invention is difficult, that is, the electronic device has extremely high security level. In addition, the electronic device can have improved functionality and convenience, for example.

Examples of the electronic device include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device 6500 in FIG. 16A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 16B is a schematic cross-sectional view including an end portion of the housing 6501 on the microphone 6506 side.

A protective component 6510 that transmits light is provided on the display surface side of the housing 6501. A display panel 6511, an optical component 6512, a touch sensor panel 6513, a printed circuit board 6517, a battery 6518, and the like are provided in a space surrounded by the housing 6501 and the protective component 6510.

The display panel 6511, the optical component 6512, and the touch sensor panel 6513 are fixed to the protective component 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be provided. Since the display panel 6511 is extremely thin, the battery 6518 with high capacity can be mounted without an increase in the thickness of the electronic device. An electronic device with a narrow frame can be obtained when part of the display panel 6511 is folded back so that the portion connected to the FPC 6515 is positioned on the rear side of a pixel portion.

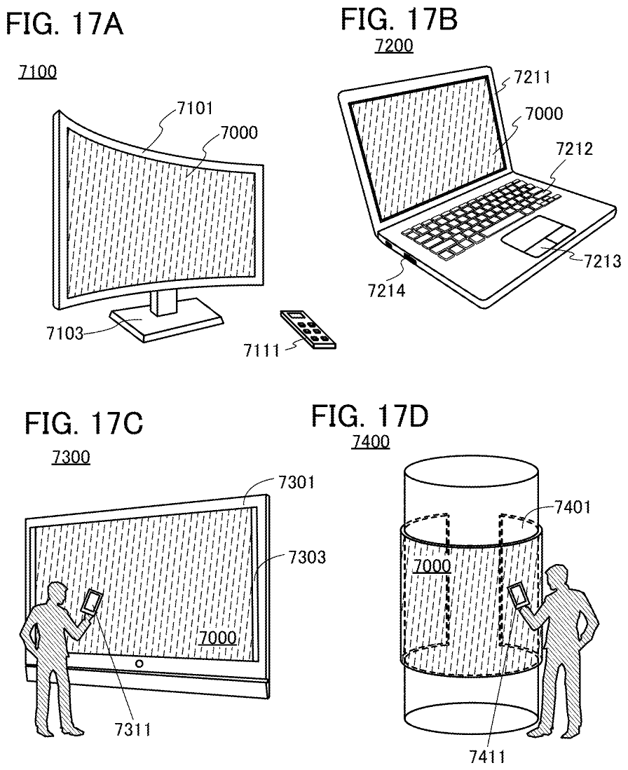

FIG. 17A illustrates an example of a television device. In a television device 7100, a display portion 7000 is incorporated in a housing 7101. Here, a structure in which the housing 7101 is supported by a stand 7103 is illustrated.

The display device of one embodiment of the present invention can be used in the display portion 7000.

The television device 7100 illustrated in FIG. 17A can be operated with an operation switch provided in the housing 7101 or a separate remote controller 7111. Alternatively, the display portion 7000 may include a touch sensor, and the television device 7100 may be operated by a touch on the display portion 7000 with a finger or the like. The remote controller 7111 may be provided with a display portion for displaying information output from the remote controller 7111. With a touch panel or operation keys provided in the remote controller 7111, channels and volume can be controlled, and videos displayed on the display portion 7000 can be controlled.

Note that the television device 7100 is provided with a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 17B illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIGS. 17C and 17D illustrate examples of digital signage.

Digital signage 7300 illustrated in FIG. 17C includes a housing 7301, the display portion 7000, a speaker 7303, and the like. Furthermore, the digital signage can include an LED lamp, operation keys (including a power switch or an operation switch), a connection terminal, a variety of sensors, a microphone, and the like.

FIG. 17D illustrates digital signage 7400 mounted on a cylindrical pillar 7401. The digital signage 7400 includes the display portion 7000 provided along a curved surface of the pillar 7401.

The display device of one embodiment of the present invention can be used in the display portion 7000 illustrated in each of FIGS. 17C and 17D.

A larger area of the display portion 7000 can increase the amount of data that can be provided at a time. The larger display portion 7000 attracts more attention, so that the effectiveness of the advertisement can be increased, for example.

It is preferable to use a touch panel in the display portion 7000 because in addition to display of a still image or a moving image on the display portion 7000, intuitive operation by a user is possible. Moreover, for an application for providing information such as route information or traffic information, usability can be enhanced by intuitive operation.

It is preferable that the digital signage 7300 or the digital signage 7400 work with an information terminal 7311 or an information terminal 7411 such as a user's smartphone through wireless communication, as illustrated in FIGS. 17C and 17D. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

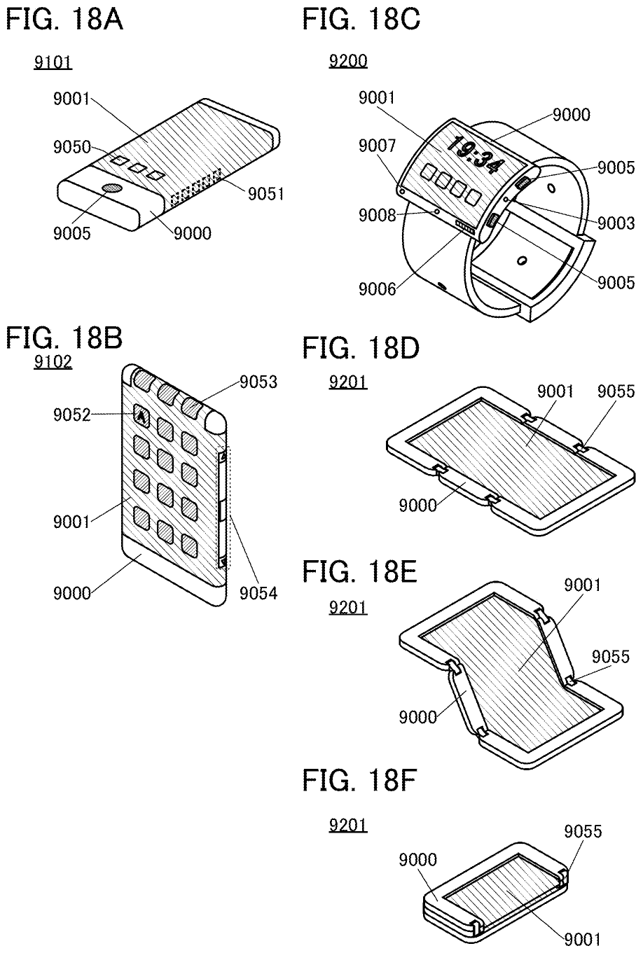

Electronic devices illustrated in FIGS. 18A to 18F include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIGS. 18A to 18F have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may include a camera or the like and have a function of taking a still image or a moving image and storing the taken image in a recording medium (an external recording medium or a recording medium incorporated in the camera), a function of displaying the taken image on the display portion, or the like.

The electronic devices illustrated in FIGS. 18A to 18F are described in detail below.

FIG. 18A is a perspective view illustrating a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display text and image information on its plurality of surfaces. FIG. 18A illustrates an example where three icons 9050 are displayed. Information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the reception strength of an antenna. Alternatively, the icon 9050 or the like may be displayed at the position where the information 9051 is displayed.

FIG. 18B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, the user can check the information 9053 displayed at a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 18C is a perspective view illustrating a watch-type portable information terminal 9200. A display surface of the display portion 9001 is curved, and display can be performed along the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 18D, 18E, and 18F are perspective views showing a foldable portable information terminal 9201. FIG. 18D is a perspective view of an opened state of the portable information terminal 9201, FIG. 18F is a perspective view of a folded state thereof, and FIG. 18E is a perspective view of a state in the middle of change from one of FIG. 18D and FIG. 18F to the other. The portable information terminal 9201 is highly portable in the folded state and is highly browsable in the opened state because of a seamless large display region. The display portion 9001 of the portable information terminal 9201 is supported by three housings 9000 joined by hinges 9055. For example, the display portion 9001 can be folded with a radius of curvature of greater than or equal to 0.1 mm and less than or equal to 150 mm.

At least part of this embodiment can be implemented in combination with any of the other embodiments described in this specification as appropriate.

### REFERENCE NUMERALS

C1, C2: capacitor, M1 to M3, M5 to M8: transistor, V1, V2, V3: wiring, 10: display device, 11: display portion, 12 to 14: driver circuit portion, 15: circuit portion, 21, 30: pixel, 21B, 21G, 21R: subpixel, 22: imaging pixel, 310, 310a, 350, 350a: transistor, 311, 351: semiconductor layer, 311i: channel formation region, 311n: low-resistance region, 312, 316, 321 to 326, 352: insulating layer, 313, 314a, 314b, 315, 331, 333, 341, 353, 354a, 354b, 355: conductive layer, 330: light-emitting element, 332: light-emitting layer, 340: light-receiving element, and 342: active layer.

This application is based on Japanese Patent Application Serial No. 2019-203123 filed with Japan Patent Office on Nov. 8, 2019, the entire contents of which are hereby incorporated by reference.

1. A display device comprising:
a first pixel circuit; and
a second pixel circuit,
wherein the first pixel circuit comprises a light-receiving element and a first transistor,
wherein the second pixel circuit comprises a light-emitting element and a second transistor,
wherein the light-receiving element comprises a first pixel electrode, an active layer, and a common electrode,
wherein the light-emitting element comprises a second pixel electrode, a light-emitting layer, and the common electrode,
wherein the first pixel electrode and the second pixel electrode are positioned on a same plane,
wherein the active layer is positioned over the first pixel electrode,
wherein the active layer comprises a first organic compound,
wherein the light-emitting layer is positioned over the second pixel electrode,
wherein the light-emitting layer comprises a second organic compound different from the first organic compound,
wherein the common electrode comprises a portion overlapping with the first pixel electrode with the active layer therebetween, and a portion overlapping with the second pixel electrode with the light-emitting layer therebetween,
wherein one of a source and a drain of the first transistor is electrically connected to the first pixel electrode,
wherein one of a source and a drain of the second transistor is electrically connected to the second pixel electrode, and
wherein the first transistor and the second transistor comprise polycrystalline silicon in their respective semiconductor layers.

2. The display device according to claim 1,
wherein each of the first transistor and the second transistor comprises a first gate and a second gate that overlap with each other with the semiconductor layer therebetween, and
wherein the first gate and the second gate are electrically connected to each other.

3. A display device comprising:
a first pixel circuit; and
a second pixel circuit,
wherein the first pixel circuit comprises a light-receiving element and a first transistor,
wherein the second pixel circuit comprises a light-emitting element and a second transistor,
wherein the light-receiving element comprises a first pixel electrode, an active layer, and a common electrode,
wherein the light-emitting element comprises a second pixel electrode, a light-emitting layer, and the common electrode,
wherein the first pixel electrode and the second pixel electrode are positioned on a same plane,
wherein the active layer is positioned over the first pixel electrode,
wherein the active layer comprises a first organic compound,
wherein the light-emitting layer is positioned over the second pixel electrode,
wherein the light-emitting layer comprises a second organic compound different from the first organic compound,
wherein the common electrode comprises a portion overlapping with the first pixel electrode with the active layer therebetween, and a portion overlapping with the second pixel electrode with the light-emitting layer therebetween,
wherein one of a source and a drain of the first transistor is electrically connected to the first pixel electrode,
wherein one of a source and a drain of the second transistor is electrically connected to the second pixel electrode,
wherein the first transistor comprises a first semiconductor layer comprising a metal oxide, and
wherein the second transistor comprises a second semiconductor layer comprising polycrystalline silicon.

4. The display device according to claim 3,
wherein the first transistor comprises a third gate positioned over the first semiconductor layer and a fourth gate overlapping with the third gate with the first semiconductor layer therebetween,
wherein the second transistor comprises a fifth gate positioned over the second semiconductor layer and a sixth gate overlapping with the fifth gate with the second semiconductor layer therebetween, and
wherein the fourth gate and the fifth gate are positioned on a same plane and comprise a same metal element.

5. The display device according to claim 3,
wherein the source and the drain of the first transistor and the source and the drain of the second transistor are positioned on a same plane and comprise a same metal element.

6. The display device according to claim 1, further comprising a common layer,
wherein the common layer comprises a portion overlapping with the active layer between the first pixel electrode and the common electrode and a portion overlapping with the light-emitting layer between the second pixel electrode and the common electrode.

7. The display device according to claim 1, further comprising:
a first common layer; and
a second common layer,
wherein the first common layer comprises a portion positioned between the first pixel electrode and the active layer and a portion positioned between the second pixel electrode and the light-emitting layer, and
wherein the second common layer comprises a portion positioned between the active layer and the common electrode and a portion positioned between the light-emitting layer and the common electrode.

8. The display device according to claim 1,
wherein the first pixel circuit comprises a third transistor, and
wherein the third transistor comprises polycrystalline silicon in its semiconductor layer.

9. The display device according to claim 1,
wherein the second pixel circuit comprises a fourth transistor, and
wherein the fourth transistor comprises a metal oxide in its semiconductor layer.

10. The display device according to claim 1, further comprising:
a first substrate; and
a second substrate,
wherein the first transistor and the second transistor are positioned between the first substrate and the second substrate,
wherein the first pixel electrode is positioned between the first transistor and the second substrate,
wherein the second pixel electrode is positioned between the second transistor and the second substrate, and
wherein the first substrate and the second substrate are flexible.

11. A display module comprising:
the display device according to claim 1; and
a connector or an integrated circuit.

12. An electronic device comprising:
the display module according to claim 11; and
at least one of an antenna, a battery, a housing, a camera, a speaker, a microphone, and an operation button.

13. The display device according to claim 3, further comprising a common layer,
wherein the common layer comprises a portion overlapping with the active layer between the first pixel electrode and the common electrode and a portion overlapping with the light-emitting layer between the second pixel electrode and the common electrode.

14. The display device according to claim 3, further comprising:
a first common layer; and
a second common layer,
wherein the first common layer comprises a portion positioned between the first pixel electrode and the active layer and a portion positioned between the second pixel electrode and the light-emitting layer, and
wherein the second common layer comprises a portion positioned between the active layer and the common electrode and a portion positioned between the light-emitting layer and the common electrode.

15. The display device according to claim 3,
wherein the first pixel circuit comprises a third transistor, and
wherein the third transistor comprises polycrystalline silicon in its semiconductor layer.

16. The display device according to claim 3,
wherein the second pixel circuit comprises a fourth transistor, and
wherein the fourth transistor comprises a metal oxide in its semiconductor layer.

17. The display device according to claim 3, further comprising:
a first substrate; and
a second substrate,
wherein the first transistor and the second transistor are positioned between the first substrate and the second substrate,
wherein the first pixel electrode is positioned between the first transistor and the second substrate,
wherein the second pixel electrode is positioned between the second transistor and the second substrate, and
wherein the first substrate and the second substrate are flexible.

18. A display module comprising:
the display device according to claim 3; and
a connector or an integrated circuit.

19. An electronic device comprising:
the display module according to claim 18; and
at least one of an antenna, a battery, a housing, a camera, a speaker, a microphone, and an operation button.
